(19) United States
(12) Patent Application Publication
(10) Pub. No.: US 2017/0263686 A1
(43) Pub. Date: Sep. 14, 2017

(54) IMAGE SENSORS INCLUDING THOSE PROVIDING GLOBAL ELECTRONIC SHUTTER

(71) Applicant: InVisage Technologies, Inc., Newark, CA (US)

(72) Inventors: Zachary Michael Beiley, Oakland, CA (US); Edward Hartley Sargent, Toronto (CA)

(21) Appl. No.: 15/456,303

(22) Filed: Mar. 10, 2017

Related U.S. Application Data
(60) Provisional application No. 62/306,998, filed on Mar. 11, 2016.

(51) Int. Cl. H01L 27/30; H04N 5/374; H04N 5/355; H01L 51/42; H01L 51/44

(52) U.S. Cl. CPC H01L 27/307; H01L 51/4226; H01L 51/447; H04N 5/35545; H04N 5/3559; H04N 5/374

(57) ABSTRACT

Various embodiments include an image sensor providing global electronic shutter having an integrated circuit, a first charge-extracting layer, an optically sensitive layer, and a second hole-extracting layer. In a first mode (the ‘on’ mode), electrons are extracted via the first charge-extracting layer. In a second mode (the ‘off’ mode), the extraction of holes is prevented by the first charge-extracting layer. Other embodiments are disclosed.

This application claims the benefit of priority to U.S. Provisional Patent Application No. 62/306,998, filed Mar. 11, 2016, and entitled, “HIGH-PERFORMANCE IMAGE SENSORS INCLUDING THOSE PROVIDING GLOBAL ELECTRONIC SHUTTER,” which is hereby incorporated by reference in its entirety.

### TECHNICAL FIELD

The present invention generally relates to optical and electronic devices, systems and methods that include optically sensitive material, such as nanocrystals or other optically sensitive material, and methods of making and using the devices and systems.

### BACKGROUND

Optoelectronic devices, such as image sensors and photovoltaic devices, can include optically sensitive material. Example image sensors include devices that use silicon both for the sensing function and for the read-out electronics and multiplexing functions. In some image sensors, optically sensitive silicon photodiodes and electronics can be formed on a single silicon wafer. Other example image sensors can employ a distinct material, such as InGaAs (e.g., for short-wave IR sensing), or amorphous selenium (e.g., for x-ray sensing), for the sensing (photon to electron conversion) function. Example photovoltaic devices include solar cells that use crystalline silicon wafers for photon to electron conversion. Other example photovoltaic devices can use a separate layer of material such as amorphous silicon or poly crystalline silicon or a distinct material for photon to electron conversion. However, these image sensors and photovoltaic devices have been known to have a number of limitations.

### INCORPORATION BY REFERENCE

Each patent, patent application, and/or publication mentioned in this specification is herein incorporated by reference in its entirety to the same extent as if each individual patent, patent application, and/or publication was specifically and individually indicated to be incorporated by reference.

### BRIEF DESCRIPTION OF THE DRAWINGS

FIG. 1A shows a materials stack, under an embodiment;

FIG. 1B shows an embodiment of a quantum dot (QD) and an interface between different semiconductor materials of one layer of the materials stack of FIG. 1A;

FIG. 2 shows a cross-section of the materials stack over a portion of a pixel, under an embodiment;

FIG. 3 shows a cross-section of the materials stack over a pixel, under an embodiment;

FIG. 4 shows a cross-section materials stack of an embodiment with two pixels;

FIGS. 5A and 5B (also collectively referred to as FIG. 5) shows voltages on pixels as a function of time;

FIG. 6 shows voltages on pixels as a function of time;

FIG. 7 shows photocurrent vs. voltage curves for two different embodiments;

FIGS. 8A-8C (also collectively referred to as FIG. 8) show energy band diagrams according to embodiments;

FIGS. 9A-9C (also collectively referred to as FIG. 9) show energy band diagrams according to embodiments; and

FIG. 10 shows three mechanisms for hole transfer according to embodiments.

### DETAILED DESCRIPTION

An optically sensitive device is described below. The device comprises a first contact and a second contact, each having a work function, and an optically sensitive material between the first contact and the second contact. The optically sensitive material comprises a p-type semiconductor, and the optically sensitive material has a work function. The device comprises circuitry that applies a bias voltage between the first contact and the second contact. The magnitude of the work function of the optically sensitive material is at least about 0.4 eV greater than the magnitude of the work function of the first contact, and also at least about 0.4 eV greater than the magnitude of the work function of the second contact. The optically sensitive material has an electron lifetime that is greater than the electron transit time from the first contact to the second contact when the bias is applied between the first contact and the second contact. The first contact provides injection of electrons and blocking the extraction of holes. The interface between the first contact and the optically sensitive material provides a surface recombination velocity less than about 1 cm/s.

An optically sensitive device is described below. The device comprises a first contact, an n-type semiconductor, an optically sensitive material comprising a p-type semiconductor, and a second contact. The optically sensitive material and the second contact each have a work function shallower than about 4.5 eV. The device comprises circuitry that applies a bias voltage between the first contact and the second contact. The optically sensitive material has an electron lifetime that is greater than the electron transit time from the first contact to the second contact when the bias is applied between the first contact and the second contact. The first contact provides injection of electrons and blocks the extraction of holes. The interface between the first contact and the optically sensitive material provides a surface recombination velocity less than about 1 cm/s.

A photodetector is described below. The photodetector comprises a first contact and a second contact, each having a work function. The photodetector comprises an optically sensitive material between the first contact and the second contact, the optically sensitive material comprising a p-type semiconductor, and the optically sensitive material having a work function. The photodetector comprises circuitry that applies a bias voltage between the first contact and the second contact. The magnitude of the work function of the optically sensitive material is at least about 0.4 eV greater than the magnitude of the work function of the first contact, and also at least about 0.4 eV greater than the magnitude of the work function of the second contact. The photodetector comprises circuitry that applies a bias voltage between the first contact and the second contact. The optically sensitive material provides a responsivity of at least about 0.8 A/W when the bias is applied between the first contact and the second contact.

In the following description, numerous specific details are introduced to provide a thorough understanding of, and enabling description for, embodiments of the systems and methods. One skilled in the relevant art, however, will recognize that these embodiments can be practiced without one or more of the specific details, or with other components, systems, etc. In other instances, well-known structures or operations are not shown, or are not described in detail, to avoid obscuring aspects of the disclosed embodiments.

Image sensors incorporate arrays of photodetectors. These photodetectors sense light, converting it from an optical to an electronic signal. Following is a description of numerous features, any one or a combination of which can be found in the photodetectors of an embodiment; the embodiments herein are not, however, limited to only these features.

The photodetectors of an embodiment are readily integrable with other circuitry related to the image sensing function, such as circuits which store charge, circuits which relay signal levels to the periphery of the array, circuits which manipulate these signal levels in the analog domain, circuits which convert analog into digital signals, and circuits which process image-related data in the digital domain.

The photodetectors of an embodiment provide a maximum of sensitivity to light within the wavelength band, or bands, of interest, along with low dark current. Sensitivity is often quantified using the measure signal-to-noise ratio (SNR) at a given level of illumination. Signal is maximized when the responsivity, quantum efficiency, or gain of the device is maximized. Noise is minimized when random fluctuations in electronic signals are minimized, subject to the limits prescribed by natural fluctuations in electrical currents and voltages at a given temperature. Relatedly, noise and other uncontrolled or difficult-to-predict variations in background signal are generally minimized when the magnitude of dark current is minimized.

The photodetectors of an embodiment provide a response time that is relatively fast when compared to conventional photodetectors formed using conventional processing methods. Applications such as video imaging and shutterless still-image acquisition typically require photodetectors whose signal levels change substantially completely in response to a transient within fewer than about 100 milliseconds (10 frames per 15 second), or fewer than about 33 milliseconds (30 frames per second), or even about 1 millisecond (1/1000 second exposure of a still image).

The photodetectors of an embodiment provide for the detection of a wide range of light intensities in a manner that can conveniently be processed by conventional electronic circuitry. This feature is known as providing high dynamic range. One method of providing high dynamic range is to compress the measured electronic response as a function of the incident optical stimulus. Such compression can be referred to as a sublinear, i.e. a nonlinear with decreasing slope, dependence of electrical signal on incident intensity. High dynamic range can also be facilitated by employing a photodetector whose gain can be controlled, such as through the selection of a voltage bias known to produce a specific gain.

The photodetectors of an embodiment can provide for the discrimination among different spectral bands of electromagnetic radiation. Of particular interest are the x-ray, ultraviolet, visible (including blue, green, and red), near-infrared, and short-wavelength infrared bands.

A description follows of methods and processes for creating, integrating (e.g., with circuits), and exploiting in a variety of applications top-surface photodetectors or arrays of photodetectors.

The photodetectors, and arrays of photodetectors, described herein can readily be integrated with other portions of image sensor circuits and systems by methods such as spin-coating sp ray-coating, drop-coating, sputtering, physical yap or deposition, chemical yap or deposition, and self-assembly, to name a few. Embodiments include exchanging ligands passivating nanoparticle surfaces for shorter ligands that will provide for appropriate charge carrier mobilities once films are formed. Embodiments include solution-phase exchanges which enable the realization of smooth-morphology films necessary to the realization of image sensors having acceptable consistent dark currents and photoresponses across an array.

The photodetectors described herein provide relatively maximum sensitivity. They maximize signal by providing photoconductive gain. Values for photoconductive gain range from about 1 to about 50, resulting in responsivities in, for example, the visible wavelengths ranging from about 0.4 A/W to about 20 A/W. In embodiments, the photodetectors described herein minimize noise by fusing nanocrystal cores such as to ensure substantially non-noise-degrading electrical communication among the particles making up the optically sensitive layer through which current flows. In embodiments, the photodetectors described herein minimize dark current by minimizing the net doping of the active layer, thus ensuring that the dark carrier density, and thus the dark conductance, of these optically sensitive materials is minimized. In embodiments, the photodetectors described herein minimize dark current by providing an electrode-to-nanocrystalline-layer electrical connection that blocks for example one type of carrier, including potentially the majority carrier at equilibrium. In embodiments, cross-linking molecules are employed that utilize chemical functionalities that remove oxides, sulfates, and/or hydroxides responsible for p-type doping. Thus, in embodiments, a more intrinsic or even n-type optically sensitive layer can be provided, leading to lowered dark currents. In embodiments, many steps in quantum dot synthesis and/or processing and/or device packaging can be performed in a controlled environment such as a Schlenk line or Glove Box; and optically sensitive layers can be encapsulated using substantially impermeable layers such as oxides, oxy nitrides, or polymers such as polyxylylene, or epoxies, in order to prevent reactive gases such as oxygen or water from significantly permeating the optically sensitive layer. In this manner, combinations of properties such as gain, dark current, and lag can be preserved over the useful lifetime of an image sensor.

The photodetectors described herein provide a time-domain response that can be as rapid as approximately sub-100 milliseconds, sub-30 milliseconds, and sub-1 millisecond. In embodiments, this is achieved by providing gain-providing (and persistence-providing) trap states associated with the optically sensitive layer that trap at least one type of carrier for only a limited time period such as 100 milliseconds, 30 milliseconds, or sub-1 millisecond. In embodiments, PbS nanoparticles are decorated with PbSO3, an oxide of PbS, which is shown to have a trap state lifetime in the vicinity of approximately 20-30 milliseconds, providing for a transient response suited to many video imaging applications. In embodiments, photodiodes are instead provided based on colloidal quantum dot layers, wherein two electrical contacts having appreciably different work functions are employed to contact the active layer. In embodiments, dark currents can be minimized through operation of such devices without the application of an appreciable external voltage bias. In embodiments, cross-linking moieties such as benzenedithiol, a bidentate linker, can be employed to remove and/or passivate certain trap states that can be present, or can develop, in such materials.

The photodetectors described herein provide enhanced dynamic range by producing a sublinear dependence of electrical signal (such as photocurrent). Over a region of low to middling intensities, trap states are available to become filled, and escape occurs following some moderate persistence, or trap state, lifetime, such as 30 milliseconds for example. At higher intensities, these trap states become substantially filled, such that charge carriers experience shorter lifetimes, or persistence times, corresponding to lower differential gains. As a result, these devices exhibit substantially constant gains over a range of low to middling intensities, followed by a gentle roll-off in gain at higher intensities. Put another way, at low to middling intensities, photocurrent depends approximately linearly on intensity, but at higher intensities, photocurrent exhibits sublinear dependence on intensity. In embodiments, photodetectors are provided wherein photoconductive gain depends on the bias applied to a device. This arises because gain is proportional to carrier lifetime divided by carrier transit time, and transit time varies in inverse proportionality with applied field. In embodiments, circuits are developed that exploit this dependence of gain on bias to increase dynamic range.

In embodiments, photodetectors described herein are readily altered, or ‘tuned’, to provide sensitivity to different spectral bands. Tuning is provided herein through the quantum size effect, whereby nanoparticle diameter is decreased, in cases through synthetic control, to increase the effective bandgap of the resulting quantum dots. Another method of tuning is provided through the choice of materials composition, wherein the use of a material having a larger bulk bandgap generally facilitates the realization of a photodetect or with responsivity onset at a relatively higher photon energy. In embodiments, photodetectors having different absorption onsets can be superimposed to form vertical pixels, wherein pixel(s) closer to the source of optical signal absorb and sense higher-energy bands of electromagnetic radiation, whereas pixel(s) further from the source of optical signal absorb and sense lower-energy bands.

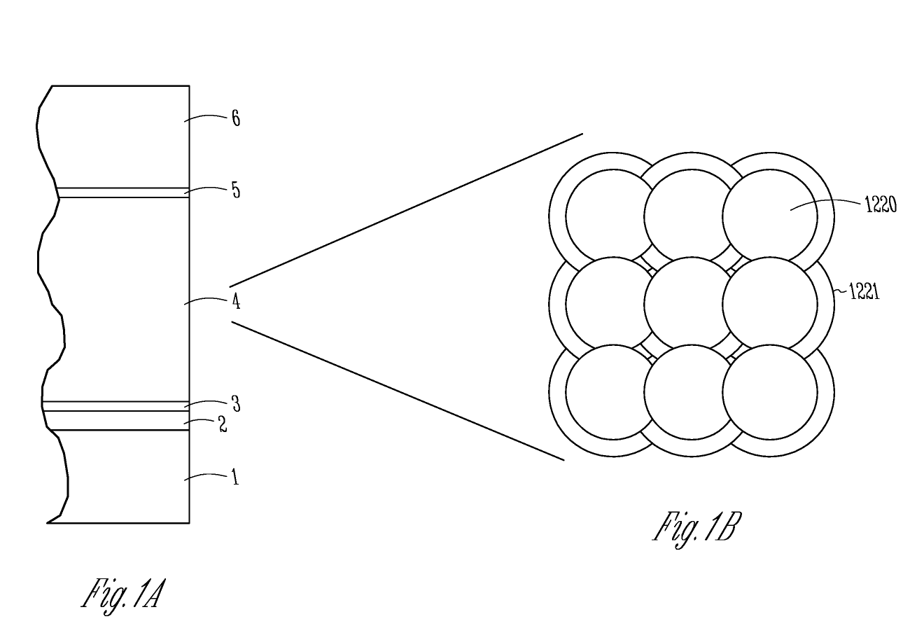

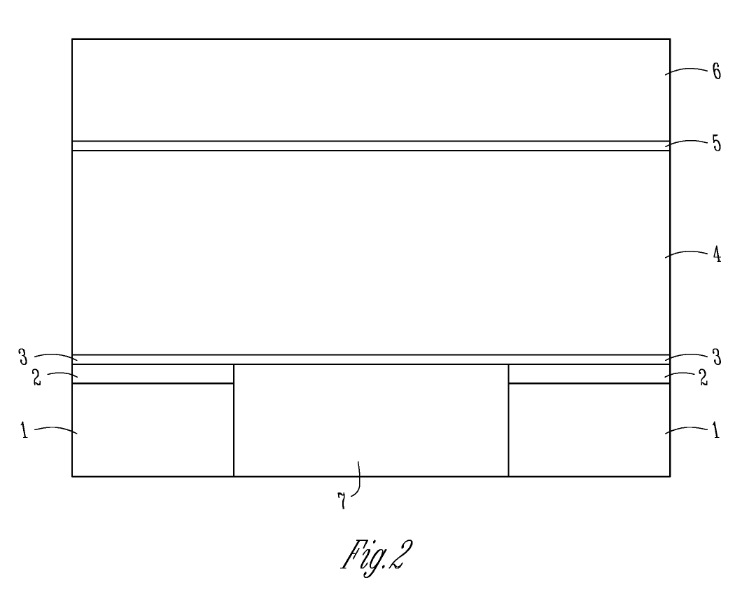

FIG. 1A shows a materials stack, under an embodiment. The materials stack is integrated with complementary metal-oxide-semiconductor (CMOS) silicon circuitry, but is not so limited. The use of CMOS silicon circuitry to read the signals transduced by photoconductive photodetectors, including top -surface photodetectors, and including those based on colloidal quantum dots including PbS, includes the integration of top-surface photoconductive materials with silicon CMOS electronics. The structure and composition of the photoconductive photodetector is described in detail below.

FIG. 2 shows a cross-section of the materials stack over a portion of a pixel, under an embodiment. The figure depicts, in the left and right hand sides or regions, the same materials stack referenced in FIG. 1. In the lateral middle of the device is incorporated a discontinuity in the material metal ‘1’ which is replaced by material ‘7.’ Material ‘7’ can in general be an insulator such as SiO2 or SiOₓN_{y}. Embodiments of FIG. 2 can be referred as a portion of a lateral pixel. In embodiments, current substantially flows between metals ‘1’ through material ‘2’ (interface), material ‘3’ (adhesion), and material ‘4’ (photosensitive layer). Different portions or regions of the materials stack described herein are referred to herein as “materials” or “layers” but are not so limited.

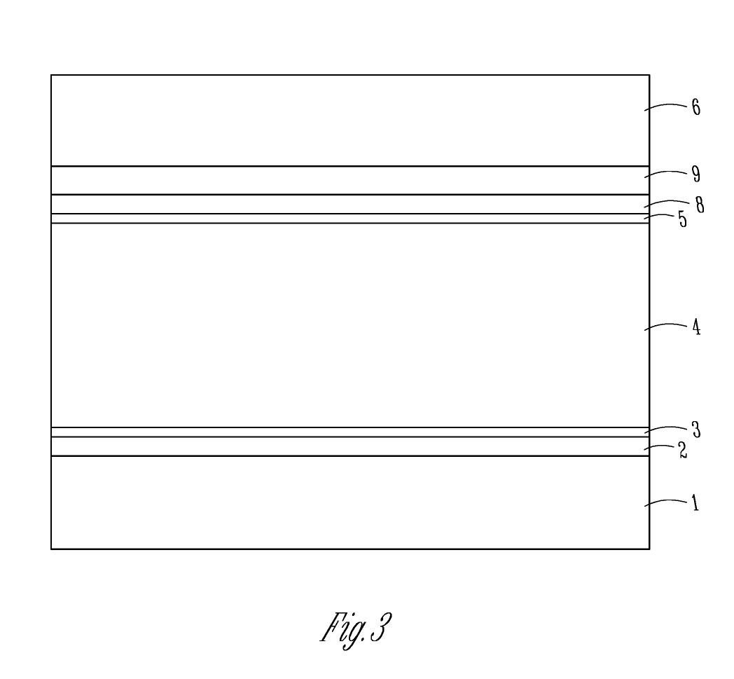

FIG. 3 shows a cross-section of the materials stack over a pixel, under an embodiment. Embodiments of FIG. 3 can be referred to as a portion of a vertical pixel. The figure depicts with materials ‘1’ ‘2’ ‘3’ ‘4’ ‘5’ ‘6’ generally the same materials stack as described above with reference to FIG. 1. An interface material or layer ‘8’ is incorporated or integrated on a top portion or region of the device. Material ‘8’ comprises a member or members of the sets of materials described herein as material ‘2’. A metal or contact layer or material ‘9’ is incorporated or integrated on a top portion or region of the device. The metal or contact layer ‘9’ comprises a member or members of the sets of materials described herein as material ‘1’. In embodiments, material ‘9’ comprises a transparent conductive material such as indium tin oxide, tin oxide, or a thin (substantially non-absorbing to visible light) metal such as TiN, Al, TaN, or other metals recited below under material ‘1.’

Material ‘1’ is a metal that lies above the substrate (not shown) and can be a silicon CMOS integrated circuit. During processing it can be a 200 mm or 300 mm wafer, i.e. a wafer that has not yet been singulated to form die. Material ‘1’ refers to a metal, present at the top surface of the CMOS integrated circuit wafer, which is presented and available for physical, chemical, and electrical connection with subsequent layers. The metal can include: TiN, TiO2, TiₓN_{y}, Al, Au, Pt, Ni, Pd, ITO, Cu, Ru, TiSi, WSi2, and combinations thereof. Material ‘1’ is referred to as the contact, or the electrode, although it shall be discussed herein that the behavior of this contact is influenced by thin layers that can reside between the metal and material ‘4,’ the photoconductive quantum dot layer.

The metal can be chosen to achieve a particular work function, and can influence whether an ohmic or non-ohmic (e.g. Schottky) contact is formed with respect to the layers to which it is proximate. For example, the metal can be chosen to provide a shallow work function, such as a value generally between −2.0 eV and −4.5 eV, for example values lying between −2.0 eV and −4.2 eV.

The metal can achieve a surface roughness less than 5 nm root-mean-squared.

The metal can be patterned with a critical dimension of 0.18 micrometers or smaller. The metal can be patterned such that, pixel-to-pixel, the spacing of the electrodes (such as between a pixel center electrode and a grid) does not vary by more than a standard deviation of 1%.

The metal can be terminated with an oxide such as a native oxide—such as TiOₓN_{y} in the case of TiN. In general this oxide, or other materials atop it such as organic residues, inorganic residues such as ‘polymer,’ etc. are of a consistent and known composition thickness.

The metal can be a conductive material, where the bulk of the material constituting the metal can have a resistivity that is less than 100 microOhm*cm.

The metal can be processed such that, across the wafer, in all regions where light-sensing pixels are to be formed, it is not capped with any additional oxides or organics or contaminants.

The top surface of the wafer, prior to or after the formation of the interface layer, can comprise regions of metal and insulating material (such as an insulating oxide), such that the peak-to-valley distance of features on this surface is less than 50 nm.

Prior to the introduction of the photosensitive semiconductor layer, the leakage current flowing between a pixel electrode in the center of a 1.1×1.1 um or 1.4×1.4 um square grid electrode should be less than 0.1 fA at 3 V bias.

Layers or materials above material ‘1’ form an interface, or interface layer. Each of the layers forming the interface is described in detail below, in turn.

Material ‘2’ is the first part or portion of the interface layer, and comprises a material that resides atop the metal. Material ‘2’ can comprise a pure, clean surface of the metal. The material of this layer can include oxides, including those generally formed, either through exposure to water, oxygen, or other oxidizing species, as a result of the presence of the exposed metal; or it can be deliberately formed such as through exposure to a controlled oxidizing environment and exposures to elevated temperatures, such as in rapid thermal processing. Native oxides include, for example, the following: TiO2 and TiOₓN_{y} atop TiN; Al2O3 atop Al; Au2O3 atop Au; PtO or PtO2 on Pt; Ni2O3 atop Ni; WO3 atop W; PdO atop Pd; and oxygen-rich ITO atop ITO. It can be that such a native oxide is to be removed, such as using etching, and replaced with another layer. For example, a native oxide such as TiOₓN_{y} can be etched (using a process such as argon sputtering) and then a layer can be deposited on top of it such as a controlled oxide such as TiO2, TiOₓ, or TiOₓN_{y}. The sum of the thicknesses of native oxides and deliberately-deposited oxides can be between about 2 nm and about 20 nm.

A portion of material ‘2’ can be a material that is substantially transparent to most or all wavelengths of visible light. It can have a bandgap that is larger than 2 eV or larger than 2.5 eV or larger than 3 eV. It can be a large-bandgap doped semiconductor. It can achieve doping through stoichiometry, such as in the case of TiOₓ, where x is varied below or above material 2 in order to achieve net doping. Values of x can be typically 1.9 to achieve an excess of Ti over stoichiometric TiO2. Values of x can typically be 2.1 to achieve an excess of O over stoichiometric TiO2. TiOₓ where x is less than about 2 can be achieved by exposing stoichiometric TiO₂ to a reducing environment. The density of free electrons can be increased, corresponding to greater n-type doping by increase the extent to which initially stoichiometric TiO₂ is reduced, i.e. by decreasing x in TiOₓ more considerably relative to the value 2. TiO₂ can be doped with nitrogen in order to modify its free carrier concentration, work function, and electron affinity . TiO₂ or TiOₓ can be doped with B, C, Co, Fe. It can be a mildly n-type material such as lightly doped TiOₓ having an equilibrium carrier density of about 10̂10 cm⁻³. It can be a moderately doped n-type material such as TiOₓ having an equilibrium carrier density of about 10̂16 cm⁻³. It can be a more strongly doped n-type material such as TiOₓ having an equilibrium carrier density of about 10̂18 cm⁻³ or 10̂19 cm ⁻³. Its electron affinity can correspond energetically substantially closely with the work function of the metal. Its work function can correspond substantially closely with the work function of the metal. Its ionization potential can reside at an energy that is much deeper than the ionization potential of the optically-absorbing layer (material ‘4’ described herein). It can be terminated through annealing processes, gas-phase treatments, or chemical treatments such as exposure to organic molecules, such as to achieve a low surface recombination velocity for holes when in contact with an adjacent semiconductor layer such as the optically-absorbing layer (‘4’ discussed below).

Material ‘3’ can also be present in the interface layer, and comprises a material that can be positioned or reside atop the first portion of the interface layer. Material ‘3’ includes adsorbed organics such as organic molecules, introduced deliberate or accidentally or through some combination thereof, that reside above the metal, either in direct contact with the metal, or in direct contact with the metal oxide. These molecules are discussed in detail herein.

Embodiments include material ‘2’ while material ‘3’ is absent. Such embodiments include choices of materials in which no adhesion layer such as that provided by material ‘3’ is required. As an example, if material ‘2’ incorporates a metal such as titanium, such as if material ‘2’ incorporates TiOₓ, and if material ‘4’ incorporates a crosslinker such as mercaptobenzoic acid, in which one functional group on the mercaptobenzoic acid binds the TiOₓ, then adhesion between material ‘4’ and material ‘2’ can be provided without explicit inclusion of material ‘3’.

In embodiments, all of material ‘1’ material ‘2’ and material ‘3’ can be present. Embodiments included cases where a Schottky contact is made via the metal ‘1’ to the material ‘4’ without the deliberate introduction of a heterojunction. Embodiments included a device in which TiN or TiOₓN_{y} forms the metal ‘1’, layer ‘2’ is a clean termination of the metal ‘1,’ with no significant formation of a native oxide, an adhesion layer such as hexamethyldisilazane is provided in material ‘3’.

In embodiments, all of material ‘1’ material ‘2’ and material ‘3’ can be present. Embodiments include cases where a heterojunction is formed via the use of a large bandgap oxide in material ‘2’ to the photosensitive layer ‘4.’ Embodiments include a device in which TiN or TiOₓN_{y} forms the metal ‘1,’ layer ‘2’ includes a large-bandgap semiconductor such as TiOₓ (which can be structurally doped, impurity doped, both, or neither), and an adhesion layer such as hexamethyldisilazane can be provided in material ‘3.’

In embodiments, material ‘1’ can be aluminum metal, material ‘2’ can include a native oxide of aluminum and can include a doped conductive oxide such as doped Al₂O₃ and/or can include a large-bandgap semiconductor such as TiOₓ (which can be structurally doped, impurity doped, both, or neither), and material ‘3’ can include an adhesion layer such as hexamethyldisilazane can be provided in material ‘3.’

In embodiments, material ‘1’ can include aluminum, gallium, indium, tin, lead, bismuth, magnesium, calcium, zinc, molybdenum, titanium, vanadium, lanthanum, chromium, manganese, iron, cobalt, nickel, copper, zirconium, niobium, palladium, silver, hafnium, tantalum, tungsten, iridium, platinum, gold. In embodiments, metals used in standard CMOS such as aluminum, tungsten, tantalum, titanium, copper can be preferred.

In embodiments, material ‘2’ can include a surface of the metal and can include oxides, nitrides, or oxynitrides of aluminum, gallium, indium, tin, lead, bismuth, magnesium, calcium, zinc, molybdenum, titanium, vanadium, lanthanum, chromium, manganese, iron, cobalt, nickel, copper, zirconium, niobium, palladium, silver, hafnium, tantalum, tungsten, iridium, platinum, gold. In embodiments, it can be preferred that it include oxides, nitrides, or oxynitrides of metals used in standard CMOS such as aluminum, tungsten, tantalum, titanium, copper.

In embodiments, material ‘2’ can comp rise multiple sub layers . In embodiments, it can comprise a sublayer consisting of a metal such as aluminum, gallium, indium, tin, lead, bismuth, magnesium, calcium, zinc, molybdenum, titanium, vanadium, lanthanum, chromium, manganese, iron, cobalt, nickel, copper, zirconium, niobium, palladium, silver, hafnium, tantalum, tungsten, iridium, platinum, gold. In embodiments, it can be preferred that this sublayer can comprise metals used in standard CMOS such as aluminum, tungsten, tantalum, titanium, copper. In embodiments, material ‘2’ can comprise a further sublayer consisting of oxides, nitrides, or oxynitrides of aluminum, gallium, indium, tin, lead, bismuth, magnesium, calcium, zinc, molybdenum, titanium, vanadium, lanthanum, chromium, manganese, iron, cobalt, nickel, copper, zirconium, niobium, palladium, silver, hafnium, tantalum, tungsten, iridium, platinum, gold. In embodiments, it can be preferred that this further sub layer include oxides, nitrides, or oxynitrides of metals used in standard CMOS such as aluminum, tungsten, tantalum, titanium, copper.

The layer referred to as material ‘4’ refers to an optically-absorbing layer that includes nanocrystals, or quantum dots. A quantum dot (QD), depicted in ‘1220’ in FIG. 1B, can be a nanostructure, for example a semiconductor nanostructure, that confines a conduction band electrons, valence band holes, or excitons (bound pairs of conduction band electrons and valence band holes) in all three spatial directions. The confinement can be due to electrostatic potentials (e.g., generated by external electrodes, doping strain, impurities), the presence of an interface between different semiconductor materials (e.g., in core-shell nanocrystal systems, incorporated in ‘1221’ of FIG. 1B) or a semiconductor and another material (e.g., a semiconductor decorated by organic ligands; or by a dielectric such as an oxide such as PbO, a sulfite such as PbSO₃, a sulfate such as PbSO₄, or SiO₂ incorporated in ‘1221’ of FIG. 1B), the presence of a semiconductor surface incorporated in ‘1221’ of FIG. 1B, or a combination of one or more of these. A quantum dot exhibits in its absorption spectrum the effects of the discrete quantized energy spectrum of an idealized zero-dimensional system. The wave functions that correspond to this discrete energy spectrum are substantially spatially localized within the quantum dot, but extend over many periods of the crystal lattice of the material. In one example embodiment, the QD can have a core of a semiconductor or compound semiconductor material, such as PbS. Ligands can be attached to some or all of the outer surface or can be removed in some embodiments. In some embodiments, the cores of adjacent QDs can be fused together to form a continuous film of nanocrystal material with nanoscale features. In other embodiments, cores can be connected to one another by linker molecules. In some embodiments, trap states can be formed on the outer surface of the nanocrystal material. In some example embodiments, the core can be PbS and trap states can be formed by an oxide such as PbSO3 formed on the outer surface of core.

A QD layer can include a continuous network of fused QD cores, having outer surfaces that are of a different composition than that in the core, for example, oxidized core material such as PbSO3, or a different kind of semiconductor. The individual QD cores in the film are in intimate contact, but continue to exhibit many of the properties of individual quantum dots. For example, a lone (unfused) quantum dot has a well-characterized excitonic absorbance wavelength peak that arises from quantum effects related to its size, for example, about 1 nm to about 10 nm. The excitonic absorbance wavelength peak of the fused QDs in the film is not significantly shifted from the central absorbance wavelength that was present prior to fusing For example, the central absorbance wavelength can change by about 10% or less when fused. Thus, the QDs in the film retain their quantum effects, despite the fact that they can be an integral part of a macroscopic structure. In some embodiments, QD cores are linked by linker molecules as described further below. This allows current to flow more readily than through unlinked, unfused QDs. However, the use of linker molecules to form a continuous film of QDs instead of fusing the cores can reduce the dark current for some photoconductor and image sensor embodiments.

In some embodiments the QD layer is exceptionally radiation sensitive. This sensitivity is particularly useful for low-radiation imaging applications. At the same time, the gain of the device can be dynamically adjusted so that the QDPC saturates, that is, additional photons continue to provide additional useful information that can be discerned by the read-out electronic circuit. Tuning of gain can be conveniently achieved by changing the voltage bias, and thus the resultant electric field, across a given device, for example, a pixel. Some embodiments of QD devices include a QD layer and a custom-designed or prefabricated electronic read-out integrated circuit. The QD layer is then formed directly onto the custom-designed or pre-fabricated electronic read-out integrated circuit. The QD layer can additionally be patterned so that it forms individual islands. In some embodiments, wherever the QD layer overlies the circuit, it continuously overlaps and contacts at least some of the features of the circuit. In some embodiments, if the QD layer overlies three-dimensional features of the circuit, the QD layer can conform to these features. In other words, there exists a substantially contiguous interface between the QD layer and the underlying electronic read-out integrated circuit. One or more electrodes in the circuit contact the QD layer and are capable of relaying information about the QD layer, for example, an electronic signal related to the amount of radiation on the QD layer, to a readout circuit. The QD layer can be provided in a continuous manner to cover the entire underlying circuit, such as a readout circuit, or patterned. If the QD layer is provided in a continuous manner, the fill factor can approach about 100%, with patterning, the fill factor is reduced, but can still be much greater than a typical 35% for some example CMOS sensors that use silicon photodiodes. In many embodiments, the QD optical devices are readily fabricated using techniques available in a facility normally used to make conventional CMOS devices. For example, a layer of QDs can be solution-coated onto a pre-fabricated electronic read-out circuit using for example, spin-coating which is a standard CMOS process, and optionally further processed with other CMOS-compatible techniques to provide the final QD layer for use in the device. Because the QD layer need not require exotic or difficult techniques to fabricate, but can instead be made using standard CMOS processes, the QD optical devices can be made in high volumes, and with no significant increase in capital cost (other than materials) over current CMOS process steps.

The QD material can have an absorption cutoff approximately at the edge of the visible, such as round 650 nm. The QD material can have an absorption cutoff at longer wavelengths, in order to ensure a high absorbance over the entire visible, such as when the absorption cutoff is in the range of about 700 nm to about 900 nm.

The QD film can be deposited using conventional spin-on process, ink-jet printing process, Langmuir-Blodgett film deposition, electrokinetic sprays, or nano-imprint. The QD film can be deposited using dispensing of QD solution on a wafer at 30 RPM followed by three-step spin process.

The spectral position of the peak in the QD solution absorption can be specified to lie at 740 nm, ±10 nm. The ratio of the absorbance at the QD absorption peak near 740 nm, and the valley slightly to the blue of this peak, can be specified to be about 1.2.

The thickness of the quantum dot layer can be specified to be about 300 nm ±50 nm. The thickness of the quantum dot layer can be chosen to ensure that, over the spectral range about 400 nm to about 640 nm, greater than 90% of all light incident on the film is absorbed. The roughness (root-mean-squared) of the quantum dot film can be specified to be less than about 5 nm.

The dark current in a 1.1 μm×1.1 μm pixel can be less than about 0.5 fA under suitable bias, such as about a 3V bias. The gain can be greater than about 10 in a 1.1 um×1.1 um pixel.

Alkali metal impurities can be present at lower than about 5E17 cm⁻³ concentration in the quantum dot film. Defects greater than about 0.16 microns in size can be fewer than 20 across a 200 mm wafer. The mobility of the flowing carrier can exceed 1E-5 cm²/Vs. The loading fraction of nanocrystals in the film can exceed 30% by volume.

Incorporated into material ‘4’ can be chemical species such as PbO, PbSO₄, PbSO₃, poly-sulfates; and they can also include physically-adsorbed species such as O₂, N₂, Ar, H₂, CO₂, H₂O, and H₂S.

Incorporated into material ‘4’ can be molecules that are bound to the surface of at least one nanoparticle, or nanocrystal, or quantum dot. These can include thiol-terminated ligands such as benzenethiol, ethanethiol; carboxylate-terminated molecules such as oleic acid and formic acid; amine-terminated ligands such as pyridine, butylamine, octylamine. They can also include bidentate crosslinkers such as benzenedithiol, ethanedithiol, and butanedithiol. They can also include multidentate molecules that include (1) a backbone (2) certain sidegroups and/or end groups that bind to the nanoparticle surface, including thiols, amines, carboxylates; and (3) other functional groups such as those that confer solubility in polar, nonpolar, and partially polar solvents.

Material ‘5’ can include layers on top of ‘4’ that can provide passivation of the underlying material, including minimizing the extent of movement of species between layers ‘1’ to ‘4’ of the materials stack and the outside of the materials stack. This layer can also facilitate good physical adhesion with overlying layers such as encapsulant layers.

Material ‘6’ refers to a layer, or layers, that can be included on top of the material stack and can serve to minimize the extent of movement of species between layers ‘1’ to ‘4’ of the materials stack and the outside of the materials stack. In a planar cell configuration the quantum dot film layer can be encapsulated against oxygen and moisture diffusion using a low-temperature (less than 100° C.) PECVD SiO2, SiN, or SiOCN process providing optically transparent film suitable for further integration with CFA. The film can be specified to have a thickness of 200 nm ±10 nm. It can be specified to have a surface roughness less than 5 nm rms. Optical transmittance can exceed 99%. Adhesion can be provided to the underlying layers. An embodiment can have fewer than twenty greater-than-0.1-um p article defects across a 200 mm wafer. An embodiment can have fewer than twenty greater-than-0.1-um pinholes across a 200 mm wafer.

The nature of the interface between the electrical contact and the light-sensitive semiconductor is an important determinant of device stability and performance. For example, whether the contact is ohmic vs. Schottky, and whether the contact and semiconductor are separated by a thin interfacial layer which passivates at least one of the (semiconductor and the contact), are important in stability and performance.

The composition of the photoconductive layer—for example the presence of surface trap states on the semiconductor materials making up the photoconductor—is an important determinant of device performance and stability. In particular, photoconductive materials are often sensitive to the presence of phy sisorbed or chemisorbed species, possibly originally presented as a gas (such as O2, H2O, CO2), on the nanoparticle surfaces—these must thus be carefully controlled during processing, and an encapsulating and/or passivating layer(s) can be used, above and/or below, the photoconductive layer, to preserve consistent photoconductive features over time. Further description follows of the interface between metal and semiconductor of an embodiment as well as encapsulation of an embodiment.

The layer ‘4’ can be made from silicon, including single-crystal silicon, polycrystalline silicon, nanocrystalline silicon, or amorphous silicon including hydrogenated amorphous silicon.

The layer ‘4’ can include materials that are not substantially quantum-confined, but instead substantially retain the bandgap of a bulk semiconductor. Embodiments include crystalline or polycrystalline or nanocrystalline or amorphous embodiments of materials such as silicon, gallium arsenide, carbon, PbS, Pb Se, PbTe, Bi2S3, In2S3, Copper-Indium-Gallium-Selenide (or Sulfide), SnS, SnSe, SnTe, in which the characteristic size of any crystalline or partially-crystalline subunits is typically not smaller than the Bohr exciton radius (the characteristic spatial extent of electron-hold pairs) in the semiconductor material employed.

The interface formation of an embodiment can comprise the cleaning and termination of material ‘1’.

The interface of an embodiment can comprise an oxide formed on material ‘1’ including a native oxide as a part of material ‘2.’ The thickness of this oxide is an important determinant of device performance. Excessive oxide thicknesses (e.g., thickness exceeding about 10 nm to about 20 nm) can provide an excessive contact resistance in series with the photoconductive film, necessitating the application of an undesirably increased bias c/o the biasing circuit. In embodiments, the thickness of this native oxide is kept in the range of less than about 5 nm.

The interface of an embodiment can comprise a further thin layer as part of material ‘2,’ such as TiO₂, generally included to modify the work function of the interface with the semiconductor to be placed on top. This layer can, in embodiments, provide selectivity in favor of one type of charge carrier: for example, TiO₂ can be configured such that, at the operating bias, it efficiently injects electrons into the conduction band of the photoconductive semiconducting layer; but, at this same bias, it withdraws holes from the valence band of the photoconductive semiconducting layer with much lower effectiveness. TiO₂ can be configured such that, at the operating bias, it efficiently extracts electrons from the conduction band of the photoconductive semiconducting layer; but, at this same bias, it injects holes into the valence band of the photoconductive semiconducting layer with much lower effectiveness.

The interface of an embodiment can comprise a further thin layer as part of material ‘2,’ such as MEH-PPV, generally included to enable the flow of one type of charge carriers, such as holes, while blocking the flow of the other type, such as electrons.

The interface of an embodiment can comprise a thin layer as part of material ‘3,’ possibly a self-organized molecular monolayer, designed to anchor on one side of the molecules to the underlying layers, and at the other terminus of the molecule to anchor to the semiconductor to be placed atop, with the goal of ensuring controlled electronic communication, and also ensuring mechanical stability, for example, good adhesion between the materials making up the multilayer device.

The layered structure of an embodiment provides efficient charge carrier transfer through an interface. In embodiments, the layered structure can form a substantially ohmic contact with the photoconductive semiconductor layer, providing for little or no depletion of the semiconductor near the interface, and providing for efficient injection and extraction of at least one type (e.g., electrons, holes) of charge carrier. In embodiments, the layered structure can form a Schottky contact with the photoconductive semiconductor layer, providing an energetic barrier that must be overcome for charge carriers to be injected and/or withdrawn. In embodiments, the layered structure can form a selective contact, providing considerably more efficient injection of one type of charge carrier (e.g., electrons) than it provides extraction of the other type (e.g., holes); and/or providing considerably more efficient withdrawal of one type of charge carrier (e.g., electrons) than it provides injection of the other type (e.g., holes).

The layered structure of an embodiment provides a work function of the contact surface where the effective work function is determined by the material of the electrode, material of the interfacial layer, and its thickness.

The layered structure of an embodiment provides blocking capability to suppress the undesirable carrier transfer, for example as a layer proving electron trap states on the surface of metal electrode in case of p-semiconductor photodetect or device.

The layered structure of an embodiment provides strong bonding of the photosensitive semiconductor material to the metal electrode.

The layered structure of an embodiment provides high temperature stability of the metal electrode-semiconductor material interface.

The structure and composition of electronic devices of an embodiment with an engineered interfacial layer includes but is not limited to a metal electrode comprising a conventional material used in semiconductor manufacturing being either readily oxidized, or nitridized, or both in a chosen stoichiometric combination, such as Ti, W, Ta, Hf, Al, Cu, Cr, Ag or being resistive to oxidation or nitridization such as Au, Pt, Rh, Ir, Ru, graphite, amorpohous carbon, graphene, or carbon nanotubes. These metal electrodes can also be formed from alloys, conductive glasses, and various conductive intermetallics. The work function of the resultant electrodes can be tuned through exposure to oxygen, nitrogen, or a combination thereof at a specific temperature for a specific time.

The structure and composition of electronic devices of an embodiment includes an interfacial layer on the surface of the metal contact. The interfacial layer of an embodiment includes an oxide or intermetallic of the element of the electrode with the maximum thickness sufficient to keep the ohmic characteristics of the contact but with the minimum thickness sufficient to create electron trap states. The structure can be created or generated using PVD (physical yap or deposition), ALD (atomic layer deposition), CVD (chemical yap or deposition), ion cluster, ion beam deposition, ion implantation, anneal or other this film deposition method. Additionally, such films can be formed from aqueous and non-aqueous liquid formulations, which can include electrochemical techniques, to form hydroxides, oxides, fluorides, sulfides, sulfates, sulfites, sulphonates, phosphates, phosphonates, phosphides, nitrates, nitrites, nitrides, carbonates, carbides, and other types of salts or complexes of the metals. The average thickness of the interfacial layer can vary from a 0.1 nm-0.nm to 10 nm-50 nm depending on conductivity of the final interfacial layer, and work function of the metal electrode itself.

The interfacial layer of an embodiment includes another oxide deposited on the surface of the electrode, the oxide having been doped TiO₂, HfO₂, Al₂O₃, SiO₂, Ta₂O₅, ZnₓAl_{y} ZnₓGa_{y}O, ZnInₓSn_{y}O, and similar p-conductive materials. Again, these materials can be deposited using the methods mentioned earlier.

Additional properties of the interfacial layer are determined by the necessity to form relatively strong chemical bond, preferably covalent, to the components of the semiconductor photosensitive layer. In case none of the components of the photosensitive layer provide chemical bonding to the interfacial layer the surface of the interfacial layer is modified using organic by-functional molecules, where one type of functional group provides selective bonding to the interfacial layer surface, while the second type of functional groups provides bonding to either ligand or directly to semiconductor nanocrystals. These bonding molecules can be formed on non-conductive alkane or aryl backbone or can be formed on conductive backbone including aniline, acytelene, or other types of sp2 hybridized carbon. The functional groups to provide bonding to the oxidized surface of the electrode or surface of the interfacial layer include but are not limited to silanes, siloxanes, silizanes, primary, secondary, or tertiary amines, imides, phosphates, oximes, carboxylates. The average length of the organic molecule forming the interfacial layer can typically vary from 2 to 16 carbon atoms.

If the metal of the electrode is passive (e.g., Au, Pt, Cu, Ag, etc.) the interfacial layer can be formed from a molecule including two similar functional groups providing bonding directly to the metal surface on one side and to a nanocrystal on another side. An example would be formation of Au—S—R—S—NC bond. Again, thickness and conductivity of the organic interfacial layer defined by the required electronic device properties.

If the conductivity of the interfacial layer is exceeding the allowable limits required be the electronic device parameters (for planar electrode element) the continuous film can be patterned using conventional patterning techniques.

In each electronic device with at least two electrodes one of the electrodes can be made of a metal with one work function while another electrode can made having a different work function and/or type of conductivity (electron or hole).

For a vertical configuration of an electronic device the same approach as above is used for the bottom electrode while the interfacial layer on top is formed by deposition of organic molecules or a thin transparent layer of the semiconductor material.

Molecules described above are polymers with the degree of polymerization from approximately 1 through approximately 10,000.

In forming a device described herein, generally, the device can be formed to include a consistent, reliable combination of material ‘1’ and material ‘2’ which can be followed by the controlled formation or material ‘3’ and the optically-absorbing layer ‘4.’ For example, an embodiment can provide through material ‘1’ a highly conductive contact having resistivity less than 100 microOhm*cm and a work function lying between about −2 eV and about −4.5 V and lying between about −2 eV and about −4.2 eV. An embodiment can provide through material ‘2’ a large-bandgap layer that permits the injection of electrons into the ensuing photosensitive semiconductor layer, but blocks the extraction of holes from this layer. An embodiment can achieve a controlled thickness of a doped substantially transparent oxide, such as n-type TiOₓ, as part of the first p art of material ‘2.’ For example, an embodiment can achieve a TiOₓ thickness in the range of about 2 nm to about 20 nm, which is controlled to within about 1 nm to about 5 nm; and where the TiOₓ has a specifically-chosen carrier density of 1×10̂18 cm⁻³ with a tight band of control such as ±10% in carrier density .

Manufacturing of a stack or configuration of layers of the device described herein can comprise: (1) formation of the metal, such as via the sputtering of titanium in a nitrogen atmosphere, resulting in the formation of TiN; (2) subsequent processing that results in the formation of an interface layer such as a native oxide, such as TiOₓN_{y} or TiOₓ (it can be that this subsequent processing results in range of possible oxide thicknesses and dopings and carrier concentrations); (3) removal of the native oxide layer through an etch such as a sulfuric acid—hydrogen peroxide—deionized water etch, or an ammonium peroxide etch, or a physical etch such as argon sputtering or a reactive sputter etch such as argon and hydrogen; in an embodiment this etch completely removes the oxide; a modest overetch to ensure complete removal can be implemented; (4) an embodiment deposits a controlled thickness, controlled doping, and controlled-surface-terminated layer of an oxide such as TiOₓ, TiOₓN_{y}, or other interface layer. Methods such as physical yap or deposition (including DC sputtering RF sputtering, of a TiOₓ source, a TiN source, or a Ti source, in the presence of O₂, Na, or a combination thereof) can be employed to deposit these layers. Methods also include CVD and ALD where a precursor is first deposited on the surface of the wafer, and a reaction proceeds at a controlled temperature. In cases where TiOₓ is to be formed, precursors can be employed.

Manufacturing of a stack or configuration of layers of the device described herein can comprise: (1) Formation of the metal, such as via the sputtering of titanium in a nitrogen atmosphere, resulting in the formation of TiN; (2) In-situ transitioning to the deposition on top of this metal of an interface layer. These can include TiOₓ or TiOₓN_{y}. This layer can possess a controlled thickness, controlled doping, and controlled-surface-terminated layer of an oxide such as TiOₓ, TiOₓN_{y}, or other interface layer. Methods such as physical vapor deposition (including DC sputtering RF sputtering, of a TiOₓ source, a TiN source, or a Ti source, in the presence of O₂, N₂, or a combination thereof) can be employed to deposit these layers. Methods also include CVD and ALD where a precursor is first deposited on the surface of the wafer, and a reaction proceeds at a controlled temperature. In cases where TiO is to be formed chemical precursors can be employed.

As described above, an encapsulating and/or passivating layer(s) can be used, above and/or below, the photoconductive layer, to preserve consistent photoconductive features over time. The embodiments described herein ensure a consistent gas environment (or lack of significant presence of a gas) in the photoconductive layer. For example, vacuum, Argon, Nitrogen, Oxygen, Hydrogen, Carbon Dioxide, can be included or excluded, in various proportions and to various degrees. Embodiments can exclude Oxygen, H₂O, CO₂, and include only either the absence of gas molecules, or nonreactive materials such as Argon and/or Nitrogen. To preserve consistent photoconductive features over time, an encapsulant layer can be included whose purpose is to avoid gas exchange between the photoconductive film and the region exterior to this film. Materials employed in an embodiment for this purpose include but are not limited to: polyxylylene; As₂S₃ or As₂Se₃; Si₃N₄, SiO₂, and mixtures thereof such as SiOₓN_{y}; oxides such as TiO₂, HfO₂, Al₂O₃, SiO₂, Ta₂O₅, ZnₓAl_{y}O, ZnₓGa_{y}O, ZnInₓSn_{y}.

The encapsulant material can be preceded by a passivation layer, potentially in the form of a substantially single molecular monolayer. This first layer can serve to protect the encapsulated structure during the deposition of the encapsulant: for example, a layer of a material such as polyxylylene can first be deposited, using a procedure that does not deleteriously alter the optoelectronic behavior of the photoconductive layer, and providing protection of the photoconductive layer during ensuing encapsulation processes. It can, for example, protect the film from reactions resultant from oxygen and its radicals that are present during certain processes employed in the deposition of oxygen-containing encapsulants such as SiOₓ, SiOₓN_{y}, etc.

In embodiments, typical thicknesses of the total encapsulant stack (which can comprise multiple layers) can range from a single monolayer (typically nanometer level or slightly sub-nanometer, e.g., about 5 Å) to typically about 1 micrometer. In embodiments, typical thicknesses of the total encapsulant stack can be less than about 1 micrometer to about 2 micrometers in order to perturb minimally the optical properties of the array .

In embodiments, included in at least one of the layers ‘1’ ‘2’ 5′ can be materials that serve to getter molecules that could react with materials in the device, including materials which, if reacted, could alter the photoelectrical properties of the device. Examples of reactive molecules that could enter the device include O₂ and H₂O and O₃. Examples of materials in the device that could have their photoelectrical properties altered by such reactions include material ‘4’ NC, material ‘3’ adhesion, material ‘2’ interface, and ‘1’ metal. Examples of gettering moieties include borazons, borohydrides including tetrahydroborates, catecholborane, L-selectride, lithium borohydride, lithium triethylborohydride, sodium borohydride, and uranium borohydride. Examples of gettering moieties include hydrolysable siloxanes.

The devices of an embodiment can include a strong chemical bond (e.g., covalent), to the components of the semiconductor photosensitive layer. In case none of the components of the photosensitive layer provide chemical bonding to the interfacial layer the surface of the interfacial layer is modified using organic by-functional molecules, where one type of functional group provides selective bonding to the interfacial layer surface, while the second type of functional group provides bonding to either ligand or directly to semiconductor nanocrystals. These bonding molecules can be formed on non-conductive alkane or aryl backbone or can be formed on conductive backbone including aniline, acytelene, or other types of sp2 hybridized carbon. The functional groups to provide bonding to the oxide can include silanes, siloxanes, silizanes, primary, secondary, or tertiary amines, imides, phosphates, oximes, carboxylates.

Manufacturing processes of the devices of an embodiment can include a wafer p re-clean using SC1 of 30 second duration and at 20° C. in a clean dry air ambient. Manufacturing processes of the devices of an embodiment can include a rinse in de-ionized water of 30 second duration at 20° C. in a clean dry air ambient. Manufacturing processes of the devices of an embodiment can include drying the wafer involving a bake for a prescribed period of time (such as 30 seconds to 24 hours) at a prescribed temperature (such as 20, 70, 150, or 200 degrees C.) in a prescribed environment (such as clean dry air, vacuum, nitrogen, argon, or a reducing atmosphere such as hydrogen, or a controlled oxidizing atmosphere containing an inert gas such as Na or Ar and an oxidizing gas such as O₂).

Manufacturing processes of the devices of an embodiment can include the stipulation of maximum and minimum and average queue times in between other processes.

Manufacturing processes of the devices of an embodiment can include treatments of substrates and quantum dot films including exposure to ethanedithiol in acetonitrile at a prescribed temperature, such as 25 degrees C., for a prescribed time, such as 20 seconds, in a prescribed atmosphere, such as Na. Manufacturing processes of the devices of an embodiment can include treatments of substrates and quantum dot films including exposure to hexanedithiol in acetonitrile at a prescribed temperature, such as 25 degrees C., for a prescribed time, such as 20 seconds, in a prescribed atmosphere, such as N₂.

Manufacturing processes of the devices of an embodiment can include the deposition of a dielectric capping layer, such as SiO₂, at or beneath a certain temperature, such as 100° C., and to a specified thickness of dielectric capping layer such as 100 degrees C.

Manufacturing processes of the devices of an embodiment can include lithographic definition of areas to be etched, followed by etching of materials, including SiO₂.

Manufacturing processes of the devices of an embodiment can include the deposition of a dielectric capping layer, such as SiN, at or beneath a certain temperature, such as 100 degrees C., and to a specified thickness of dielectric capping layer such as 100 degrees C.

Manufacturing processes of the devices of an embodiment can include lithographic definition of areas to be etched, followed by etching of materials, including SiN.

Manufacturing processes of the devices of an embodiment can include silicon CMOS manufacturing including processing on 200 mm Si wafers and a standard Al/SiO₂ material technology at 0.11 micron nodes prior to deposition of the quantum dot layer. The CMOS manufacturing flow can be completed with a patterned metal contact such as TiN.

Manufacturing processes of the devices of an embodiment can include integration of one Cu/TEO S/SiN HM single damascene layer on top of a via layer followed by selective electroless deposition of Ni/Au stack.

Manufacturing processes of the devices of an embodiment can include substrate pre-treatment. Metal electrode and/or dielectric surface modification might be required to improve electrical contact or adhesion between the layers. Instead of wet preclean the wafer might be treated by plasma or by a liquid-phase or vapor-phase process to form adhesion mono layers with controlled barrier height and density of surface states.

Manufacturing processes of the devices of an embodiment can include the deposition of photosensitive films in which tight control over the ambient atmosphere is provided to minimize and/or control the impact of oxygen and moisture on film performance. They can include the use of production tools equipped with O₂ and H₂O process monitors. Standard operating procedures can be provided that ensure minimal, or controlled and consistent, exposure of materials (such as quantum dots and layers thereof) to air, including during chemical storage, and transfer of fluids from storage containers to process tool tanks. Manufacturing processes can be compatible with chloroform and other solvents.

Manufacturing processes of the devices of an embodiment can include stabilizing the layer of quantum dots. These can include chemical post-treatment using diluted solutions of dithiols in acetonitrile.

Due to high sensitivity of QF to oxygen and moisture in ambient the queue time between QF deposition and post-treatments should be minimized and be done under an N₂ blanket. The same conditions apply to the queue time between post-treatment B and dielectric cap deposition.

Manufacturing processes of the devices of an embodiment can include the sealing of the QF film from oxygen and moisture diffusion during the lifetime of the device. Low-temperature deposition of SiO₂/SiN stack can be employed. Such processes should be performed at a substrate temperature below 100 degrees C. and at atmospheric pressure or at as high pressure as possible. Other process options can include low-temperature spin-on glass processes or ultra-thin metallic films which will not affect optical transmittance of the capping layers.

Process controls of the devices of an embodiment can include incoming wafer inspection prior to quantum dot film deposition. Inspection steps of an embodiment include: a) inspection for defect density, such as using bright field inspection; b) metal electrode work function inspection, such as using Ultraviolet Photoelectron Spectroscopy (UPS) (the UPS method process control procedure can be performed on blanket process monitor wafers); c) leakage current and dielectric voltage breakdown to be performed on TLM (test pixel array) structures. The photoelectric response of devices and film properties can be employed as part of a process control.

In embodiments, material ‘4’ can include a material having a bandgap, and providing for the absorption of light within a range of wavelengths of interest. In embodiments the photosensitive layer can include materials such as Si, PbS, PbSe, CdS, CdSe, GaAs, InP, InAs, PbTe, CdTe, Ge, In₂S₃, Bi₂S₃, and combinations thereof. In embodiments the photosensitive layer can include strongly light-absorbing materials such as porphyrins. In embodiments, the photosensitive layer can include passivating organic ligands such as ethanethiol, ethanedithiol, benzenethiol, benzenedithiol, dibenzenedithiol, pyridine, butylamine.

In embodiments, the photodetectors of an embodiment include photosensitive devices that employ a light-sensitive energetic barrier controlling the flow of at least one type of charge carrier.

In embodiments, the photodetectors can exhibit gain, wherein the ratio of the number of additional units of charge flowing each second to the number of photons impinging on a device each second can exceed unity, for example values lying in the approximately range of about 2 to about 60.

In embodiments, the photodetectors can exhibit a high normalized response, that is to say, a high ratio of photo current to dark current even at low light levels. For example, when 150 n W/cm² of visible light impinge on the photodetectors, the ratio of photo current to light current can exceed 20. In general, this value should be as high as possible (while fulfilling other specifications, such as on lag and dark current uniformity and photoresponse uniformity). Values as high as 100 and greater are possible for the normalized response at 150 nW/cm².

In embodiments, the photodetectors can exhibit a rapid temp oral response, with the photocurrent (including following intense illumination, such as about 1 μW/cm² on pixel and greater) settling to a value close to the dark current (such as one least-significant-bit from the dark current) within less than 1 second. Ideally the photo current settles to this value within one exposure period, which can be 1/15 s, 1/30 s, 1/200 s, 1/1000 s, or similar.

In embodiments, the current-voltage characteristic in the dark can exhibit, between zero and a first voltage, known as the saturation voltage, a monotonically increasing functional relationship . This range can be referred to as the turn-on phase. The current-voltage can exhibit, between the first voltage and a second, larger, voltage, known as the reach-through voltage, a monotonically increasing relationship having a lower average slope than during the zero-to-first-voltage range. This first-to-second-voltage range can be referred to as the saturation range. At voltages greater than the second, or reach-through, voltage, the current-voltage relationship can exhibit an increase in slope relative to the first-voltage-to-second-voltage range. This highest-voltage range can be termed the post-reach-through range.

In embodiments, gain can be achieved when, under bias, the time for the flowing charge carrier (for example, electrons) to transit the device (i.e., the time to travel between two contacts, such as between left-side material ‘1’ and right-side material ‘1’ in FIG. 2, or the time to travel between material ‘1’ and material ‘9’ in FIG. 3) exceeds the average lifetime of that charge carrier, when the contact that injects the flowing charge carrier (for example, electrons) also prevents the extraction of the other type of charge carrier, which can be termed the blocked carrier (for example, holes), and when the interface between the contact that provides the flowing charge carrier (for example electrons) and the semiconductor film provides a low surface recombination velocity for the blocked carrier (e.g., holes). This interface can be embodied in material ‘2’ and material ‘3’ in FIG. 1A, material ‘2’ and material ‘3’ in FIG. 2 and also material ‘7’ and material ‘3’ in FIG. 2, and material ‘2’, material ‘3’, material ‘5’ and material ‘8’ in FIG. 3.

More particularly, gain can be achieved when, under bias, the time for the flowing charge carrier (for example, electrons) to transit the device exceeds the average lifetime of that charge carrier. Quantitatively, it can be said that the base transport factor, alpha_t, is less than but close to unity. This can be achieved if the minority carrier diffusion length for the flowing carrier exceeds the separation between the interface layers.

Furthermore, gain can be achieved when, under bias, the contact that injects the flowing charge carrier (for example, electrons) also prevents the extraction of the other type of charge carrier, which can be termed the blocked carrier (for example, holes). Quantitatively, it can be said that the emitter injection efficiency, gamma, is less than but close to unity. This can be achieved by using an interface layer near the flowing-carrier-injecting contact that blocks the extraction of the other type of charge carrier. This can be achieved by making the interface layer from a large-bandgap material in which one band (such as the conduction band) is substantially closely aligned in energy with the work function of the metal contact with which it is proximate; and which is substantially misaligned in energy with the band in the semiconductor from which it is to block the extraction of charge carriers.

Moreover, gain can be achieved when, under bias, the interface between the contact that provides the flowing charge carrier (for example electrons) and the semiconductor film provides a low surface recombination velocity for the blocked carrier (e.g., holes). Quantitatively, it can be said that the recombination factor is less than, but close to, unity. This can be achieved if, within the minority carrier lifetime of the flowing carrier (e.g., electrons), only a small fraction of the blocked-carrier (e.g. holes) recombine near the interface between the contact that provides the flowing charge carrier (for example electrons) and the semiconductor film. This can require that the surface recombination velocity for the blocked carrier be less than 0.1 cm/s, for example 0.01 cm/s or less.

Referring to FIG. 2, embodiments can include methods and structures taken to reduce the dark current passing between leftmost material ‘1’ and rightmost material 1.' Embodiments can include the removal of conductive moieties in the portion of material ‘3’ that reside between the contacts leftmost material ‘1’ and rightmost material 1.' Embodiments can include the removal of conductive moieties such as metal oxides, metal hydroxides, organic contamination, polymer, conductive oxides that reside between the contacts leftmost material ‘1’ and rightmost material ‘1.’ Referring to FIG. 2, embodiments can include the modification of the interface between material ‘7’ and material ‘4’ in order to control the recombination rate, the trapped charge, the adhesion, or a plurality of such properties at this interface.

Referring to FIG. 1A, embodiments include controlling surface states such as those present in interface layers ‘2’ and ‘3.’ Embodiments include striking a metal such as TiN in material ‘1’ or a metal hydroxide such as TiOₓ in material ‘2’ with xenon or other species or employing argon sputtering in order to control or modify the recombination rate on the surface. Embodiments can include reducing the surface recombination velocity for charge carriers of one type to less than about 0.1 cm/s or to less than about 0.01 cm/s at this interface.

Embodiments include the realization of small pixels with a pixel pitch of about 0.9 μm in each lateral dimension. Embodiments include the use of narrow vias such as about 0.15 μm. Embodiments include the use of metal-to-metal spacings of about 0.14 μm.

Embodiments described herein include an optically sensitive device comprising: a first contact and a second contact, each having a work function; an optically sensitive material between the first contact and the second contact, the optically sensitive material comprising a p-type semiconductor, and the optically sensitive material having a work function; circuitry configured to apply a bias voltage between the first contact and the second contact; the magnitude of the work function of the optically sensitive material being at least about 0.4 eV greater than the magnitude of the work function of the first contact, and also at least about 0.4 eV greater than the magnitude of the work function of the second contact; the optically sensitive material having an electron lifetime that is greater than the electron transit time from the first contact to the second contact when the bias is applied between the first contact and the second contact; the first contact providing injection of electrons and blocking the extraction of holes; the interface between the first contact and the optically sensitive material providing a surface recombination velocity less than 1 cm/s.

Embodiments described herein include an optically sensitive device comprising: a first contact; an n-type semiconductor; an optically sensitive material comprising a p-type semiconductor; a second contact; the optically sensitive material and the second contact each having a work function shallower than about 4.5 eV; circuitry configured to apply a bias voltage between the first contact and the second contact; the optically sensitive material having an electron lifetime that is greater than the electron transit time from the first contact to the second contact when the bias is applied between the first contact and the second contact; the first contact providing injection of electrons and blocking the extraction of holes; the interface between the first contact and the optically sensitive material providing a surface recombination velocity less than about 1 cm/s.

Embodiments described herein include a photodetector comprising: a first contact and a second contact, each having a work function; an optically sensitive material between the first contact and the second contact, the optically sensitive material comprising a p -type semiconductor, and the optically sensitive material having a work function; circuitry configured to apply a bias voltage between the first contact and the second contact; the magnitude of the work function of the optically sensitive material being at least about 0.4 eV greater than the magnitude of the work function of the first contact, and also at least about 0.4 eV greater than the magnitude of the work function of the second contact; circuitry configured to apply a bias voltage between the first contact and the second contact; and the optically sensitive material configured to provide a responsivity of at least about 0.8 A/W when the bias is applied between the first contact and the second contact.

The first contact of the photodetector of an embodiment is an injecting contact and the second contact is a withdrawing contact.

The injecting contact of the photodetector of an embodiment is configured to inject a flowing carrier into the optically sensitive material with greater efficiency than the injecting contact withdraws a trapped carrier from the optically sensitive material.

The injecting contact of the photodetector of an embodiment is configured to withdraw a flowing carrier from the optically sensitive material with greater efficiency than the withdrawing carrier injects a trapped carrier into the optically sensitive material.

The optically sensitive material of the photodetector of an embodiment is a p-type semiconductor material.

The first contact of the photodetector of an embodiment comprises metal and wherein the second contact comprises metal.

The bias of the photodetector of an embodiment is in the range of about −0.1 Volts to about −2.8 Volts and the flowing carrier is electrons.

The optically sensitive material of the photodetector of an embodiment comprises nanoparticles selected from the group consisting of PbS, PbSe, PbTe, CdS, CdSe, CdTe, Si, Ge, or C.

Each nanoparticle of the photodetector of an embodiment includes an oxide on the surface of the nanoparticle.

An optically sensitive layer of the photodetector of an embodiment comprises a material selected from the group consisting of PbSO₄, PbO, PbSeO₄, PbTeO₄, SiOₓN_{y}, In₂O₃, sulfur, sulfates, sulfoxides, carbon, and carbonates.

The nanoparticles of the photodetector of an embodiment are interconnected.

The injecting contact and the withdrawing contact of the photodetector of an embodiment each comprise a material selected from the group consisting of Al, Ag In, Mg, Ca, Li, Cu, Ni, NiS, TiN, or TaN.

The optically sensitive layer of the photodetector of an embodiment has a dimension perpendicular to the direction of incident of light in the range of from about 100 nm to about 3000 nm.

A first carrier type of the photodetector of an embodiment is in the majority in the dark and a second carrier type is in the majority under illumination.

The first carrier type of the photodetector of an embodiment is holes and the second carrier type is electrons.

The first contact and the second contact of the photodetector of an embodiment comprise a shallow-work function metal.

The first contact and the second contact of the photodetector of an embodiment comprise each have a work function shallower than about 4.5 eV.

The distance between the first contact and the second contact of the photodetector of an embodiment is in the range of about 200 nm to about 2 μm.

The flowing carrier of the photodetector of an embodiment has a mobility of at least of at least about 1E-5 cm²/Vs.

The p -type semiconductor material of the photodetector of an embodiment is a doped p -type material.

The bias of the photodetector of an embodiment is in the range of about +0.1 Volts to about +2.8 Volts and the flowing carrier is holes.

The injecting contact and the withdrawing contact of the photodetector of an embodiment each comprise a material selected from the group consisting of Au, Pt, Pd, Cu, Ni, NiS, TiN, and TaN.

A first carrier type of the photodetector of an embodiment is in the majority in the dark and a second carrier type of the photodetector of an embodiment is in the majority under illumination.

The first carrier type of the photodetector of an embodiment is electrons and the second carrier type is holes.

The first contact and the second contact of the photodetector of an embodiment comprise a deep-work function metal.

The first contact and the second contact of the photodetector of an embodiment comprise each have a work function deeper than about 4.5 eV.

The n-type semiconductor material of the photodetector of an embodiment is a doped n-type material.

The optically sensitive material of the photodetector of an embodiment has a work function deeper than the work function of the first contact and the second contact by at least about 0.3 eV.

The first contact and the second contact of the photodetector of an embodiment each comprise a material selected from the group consisting of Al, Ag, In, Mg Ca, Li, Cu, Ni, NiS, TiN, TaN, n-type polysilicon, and n-type amorphous silicon.

Embodiments described herein include a photodetector comprising: a first contact and a second contact; an optically sensitive material between the first contact and the second contact, the optically sensitive material comprising an n-type semiconductor; the first contact and the second contact each having a work function deeper than about 4.5 eV; circuitry configured to apply a bias voltage between the first contact and the second contact; and the optically sensitive material configured to provide a photoconductive gain and a responsivity of at least about 0.4 A/W when the bias is applied between the first contact and the second contact.

The optically sensitive material of the photodetector of an embodiment has a work function shallower than the work function of the first contact and the second contact by at least about 0.3 eV.

The first contact and the second contact of the photodetector of an embodiment each comprise a material selected from the group consisting of Au, Pt, Pd, Cu, Ni, NiS, TiN, TaN, p-type polysilicon, and p-type amorphous silicon.

Embodiments described herein include a phototransistor comprising: a first contact and a second contact; an optically sensitive material between the first contact and the second contact, the optically sensitive material comprising an n-type semiconductor; the first contact and the second contact each having a Schottky contact or work function deeper than about 4.5 eV; circuitry configured to apply a bias voltage between the first contact and the second contact; and the optically sensitive material having a hole lifetime that is greater than the hole transit time from the first contact to the second contact when the bias is applied between the first contact and the second contact.

The flowing carrier of the photodetector of an embodiment is holes and the trapped carrier is electrons.

Embodiments described herein include a phototransistor comprising a first contact and a second contact; an optically sensitive material between the first contact and the second contact, the optically sensitive material comprising a p-type semiconductor; the first contact and the second contact each having a Schottky contact or work function shallower than about 4.5 eV; circuitry configured to apply a bias voltage between the first contact and the second contact; and the optically sensitive material having an electron lifetime when the bias is applied between the first contact and the second contact; wherein the electron mobility of the optically sensitive material, the distance between the first contact and the second contact and the bias voltage are selected such that the electron transit time from the first contact to the second contact is less than the electron lifetime when the bias is applied between the first contact and the second contact.

The flowing carrier of the photodetector of an embodiment is electrons and the trapped carrier is holes.

Embodiments described herein include a phototransistor comprising: a first contact and a second contact; an optically sensitive material between the first contact and the second contact, the optically sensitive material comprising an n-type semiconductor; the first contact and the second contact each having a Schottky contact or work function deeper than about 4.5 eV; circuitry configured to apply a bias voltage between the first contact and the second contact; the optically sensitive material having a hole lifetime when the bias is applied between the first contact and the second contact; wherein the hole mobility of the optically sensitive material, the distance between the first contact and the second contact and the bias voltage are selected such that the hole transit time from the first contact to the second contact is less than the hole lifetime when the bias is applied between the first contact and the second contact.

The flowing carrier of the photodetector of an embodiment is holes and the trapped carrier is electrons.

The photodetector of an embodiment comprises a p-type semiconductor comprising p-doped silicon.

The photodetector of an embodiment comp rises a p-type semiconductor comprising GaAs.

The photodetector of an embodiment comp rises a p-type semiconductor comprising quantum dots/nanocrystals.

The photodetector of an embodiment comp rises a p-type semiconductor comprising a network of interconnected nanocrystals.

The photodetector of an embodiment comp rises a p-type semiconductor comprising nanocrystals and linker molecules.

The photodetector of an embodiment comprises a p-type semiconductor comprising a compound semiconductor.

The photodetector of an embodiment comprises a p-type semiconductor comprising PbS, PbS with PBSO3.

Embodiments described herein include an optically sensitive device comprising: a first contact and a second contact, each having a work function; an optically sensitive material between the first contact and the second contact, the optically sensitive material comprising a p-type semiconductor, and the optically sensitive material having a work function; circuitry configured to apply a bias voltage between the first contact and the second contact; the magnitude of the work function of the optically sensitive material being at least about 0.4 eV greater than the magnitude of the work function of the first contact, and also at least about 0.4 eV greater than the magnitude of the work function of the second contact; the optically sensitive material having an electron lifetime that is greater than the electron transit time from the first contact to the second contact when the bias is applied between the first contact and the second contact; the first contact providing injection of electrons and blocking the extraction of holes; and the interface between the first contact and the optically sensitive material providing a surface recombination velocity less than 1 cm/s.

The work function of the first contact and the second contact of the device of an embodiment are each shallower than about 4.5 eV.

The bias of the device of an embodiment is in the range of about −0.1 Volts to about −2.8 Volts.

The optically sensitive material of the device of an embodiment comprises a plurality of nanoparticles, wherein each of the nanoparticles has an oxide on a surface of the respective nanoparticle.

The optically sensitive material of the device of an embodiment comprises nanoparticles selected from the group consisting of PbS, PbSe, PbTe, CdS, CdSe, CdTe, Si, Ge, or C.

The optically sensitive layer of the device of an embodiment comprises a material selected from the group consisting of PbSO₄, PbO, PbSeO₄, PbTeO₄, SiOₓN_{y}, In₂O₃, sulfur, sulfates, sulfoxides, carbon, and carbonates.

The optically sensitive material of the device of an embodiment comprises a plurality of interconnected nanoparticles.

The first contact and the second contact of the device of an embodiment each comprise a material selected from the group consisting of Al, Ag, In, Mg Ca, Li, Cu, Ni, NiS, TiN, or TaN, TiO₂, TiₓN_{y}, ITO, Ru, TiSi, WSi₂, TiOₓ doped with B, TiOₓ doped with C, TiOₓ doped with Co, TiOₓ doped with Fe, TiOₓ doped with Nd, TiOₓ doped with N.

The first contact and the second contact of the device of an embodiment are separated by a distance in the range of about 200 nm to about 2 μm and the electron mobility in the optically sensitive material is at least about 1E-5 cm²/Vs.

The optically sensitive material of the device of an embodiment is configured to provide a responsivity of at least about 0.8 A/W when the bias is applied between the first contact and the second contact.

Embodiments described herein include an optically sensitive device comprising: a first contact; an n-type semiconductor; an optically sensitive material comprising a p-type semiconductor; a second contact; the magnitude of the work function of the optically sensitive material being at least about 0.4 eV greater than the magnitude of the work function of the second contact; the optically sensitive material having an electron lifetime that is greater than the electron transit time from the first contact to the second contact when the bias is applied between the first contact and the second contact; the n-type semiconductor providing injection of electrons and blocking the extraction of holes; and the interface between the n-type semiconductor and the optically sensitive material providing a surface recombination velocity less than about 1 cm/s.

The n-type semiconductor of the device of an embodiment comprises a material selected from the group consisting of TiO₂, TiO₂ that has been chemically reduced, TiO₂ that has been oxidized, CdTe, CdS, CdSe, Si, or nanoparticles selected from the group consisting of PbS, Pb Se, PbTe, CdS, CdSe, CdTe, Si, Ge, or C.

The bias of the device of an embodiment is in the range of about −0.1 Volts to about −2.8 Volts.

The optically sensitive material of the device of an embodiment comprises a plurality of nanoparticles, wherein each of the nanoparticles has an oxide on a surface of the respective nanoparticle.

The optically sensitive material of the device of an embodiment comprises nanoparticles selected from the group consisting of PbS, Pb Se, PbTe, CdS, CdSe, CdTe, Si, Ge, or C.

The optically sensitive material of the device of an embodiment comprises a plurality of interconnected nanoparticles.

The first contact and the second contact of the device of an embodiment are separated by a distance in the range of about 200 nm to about 2 μm.

The first contact and the second contact of the device of an embodiment each comprise a material selected from the group consisting of Al, Ag, In, Mg Ca, Li, Cu, Ni, NiS, TiN, TaN, TiO₂, TiₓN_{y}, ITO, Ru, TiSi, WSi₂, TiOₓ doped with B, TiOₓ doped with C, TiOₓ doped with Co, TiOₓ doped with Fe, TiOₓ doped with Nd, TiOₓ doped with N.

Embodiments described herein include a photodetector comprising: a first contact and a second contact, each having a work function; an optically sensitive material between the first contact and the second contact, the optically sensitive material comprising a p-type semiconductor, and the optically sensitive material having a work function; circuitry configured to apply a bias voltage between the first contact and the second contact; the magnitude of the work function of the optically sensitive material being at least about 0.4 eV greater than the magnitude of the work function of the first contact, and also at least about 0.4 eV greater than the magnitude of the work function of the second contact; circuitry configured to apply a bias voltage between the first contact and the second contact; and the optically sensitive material configured to provide a responsivity of at least about 0.8 A/W when the bias is applied between the first contact and the second contact.

The work function of the first contact and the second contact of the photodetector of an embodiment are each shallower than about 4.5 eV.

The bias of the photodetector of an embodiment is in the range of about −0.1 Volts to about −2.8 Volts.

The optically sensitive material of the photodetector of an embodiment comprises nanoparticles selected from the group consisting of PbS, PbSe, PbTe, CdS, CdSe, CdTe, Si, Ge, or C.

The optically sensitive layer of the photodetector of an embodiment comprises a material selected from the group consisting of PbSO₄, PbO, PbSeO₄, PbTeO₄, SiOxN_{y}, In₂O₃, sulfur, sulfates, sulfoxides, carbon, and carbonates.

The first contact and the second contact of the photodetector of an embodiment each comprise a material selected from the group consisting of Al, Ag, In, Mg Ca, Li, Cu, Ni, NiS, TiN, TaN, TiO₂, TiₓN_{y}, ITO, Ru, TiSi, WSi₂, TiOₓ doped with B, TiOₓ doped with C, TiOₓ doped with Co, TiOₓ doped with Fe, TiOₓ doped with Nd, TiOₓ doped with N.

The first contact and the second contact of the photodetector of an embodiment are separated by a distance in the range of about 200 nm to about 2 μm and the electron mobility in the optically sensitive material is at least about 1E-5 cm²/Vs.

Embodiments described herein include an optically sensitive device comprising: a first contact and a second contact, each having a work function; an optically sensitive material between the first contact and the second contact, the optically sensitive material comprising an n-type semiconductor, and the optically sensitive material having a work function; circuitry configured to apply a bias voltage between the first contact and the second contact; the magnitude of the work function of the optically sensitive material being at least about 0.4 eV less than the magnitude of the work function of the first contact, and also at least about 0.4 eV less than the magnitude of the work function of the second contact; the optically sensitive material having a hole lifetime that is greater than the hole transit time from the first contact to the second contact when the bias is applied between the first contact and the second contact; the first contact providing injection of holes and blocking the extraction of electrons; and the interface between the first contact and the optically sensitive material providing a surface recombination velocity less than about 1 cm/s.

The work function of the first contact and the second contact of the device of an embodiment are each deeper than about 4.5 eV.

The bias of the device of an embodiment is in the range of about 0.1 Volts to about 2.8 Volts.

The optically sensitive material of the device of an embodiment comprises a plurality of nanoparticles, wherein each of the nanoparticles has an oxide on a surface of the respective nanoparticle.

The optically sensitive material of the device of an embodiment comprises nanoparticles selected from the group consisting of PbS, PbSe, PbTe, CdS, CdSe, CdTe, Si, Ge, or C.

The optically sensitive layer of the device of an embodiment comprises a material selected from the group consisting of PbSO₄, PbO, PbSeO₄, PbTeO₄, SiOₓN_{y}, In₂O₃, sulfur, sulfates, sulfoxides, carbon, and carbonates.

The optically sensitive material of the device of an embodiment comprises a plurality of interconnected nanoparticles.

The first contact and the second contact of the device of an embodiment each comprise a material selected from the group consisting of Au, Pd, Pt, Ag, In, Cu, Ni, NiS, NiSi, Pt Si, TiN, or TaN.

The first contact and the second contact of the device of an embodiment are separated by a distance in the range of about 200 nm to about 2 μm and the hole mobility in the optically sensitive material is at least about 1E-5 cm²/Vs.

The optically sensitive material of the device of an embodiment provides a responsivity of at least about 0.8 A/W when the bias is applied between the first contact and the second contact.

Embodiments described herein include an optically sensitive device comprising: a first contact; a p-type semiconductor; an optically sensitive material comprising an n-type semiconductor; a second contact; the magnitude of the work function of the optically sensitive material being at least about 0.4 eV less than the magnitude of the work function of the second contact; the optically sensitive material having a hole lifetime that is greater than the hole transit time from the first contact to the second contact when the bias is applied between the first contact and the second contact; the p-type semiconductor providing injection of holes and blocking the extraction of electrons; and the interface between the p-type semiconductor and the optically sensitive material providing a surface recombination velocity less than about 1 cm/s.

The p -type semiconductor of the device of an embodiment comprises a material selected from the group consisting of TiO₂, TiO₂ that has been chemically reduced, TiO₂ that has been oxidized, CdTe, CdS, CdSe, Si, or nanoparticles selected from the group consisting of PbS, Pb Se, PbTe, CdS, CdSe, CdTe, Si, Ge, or C.

The bias of the device of an embodiment is in the range of about 0.1 Volts to about 2.8 Volts.

The optically sensitive material of the device of an embodiment comprises a plurality of nanoparticles, wherein each of the nanoparticles has an oxide on a surface of the respective nanoparticle.

The optically sensitive material of the device of an embodiment comprises nanoparticles selected from the group consisting of PbS, PbSe, PbTe, CdS, CdSe, CdTe, Si, Ge, or C.

The optically sensitive material of the device of an embodiment comprises a plurality of interconnected nanoparticles.

The first contact and the second contact of the device of an embodiment are separated by a distance in the range of about 200 nm to about 2 μm.

The first contact and the second contact of the device of an embodiment each comprise a material selected from the group consisting of Au, Pd, Pt, Ag, In, Cu, Ni, NiS, NiSi, Pt Si, TiN, or TaN.

Embodiments described herein include a photodetector comprising a first contact and a second contact, each having a work function; an optically sensitive material between the first contact and the second contact, the optically sensitive material comprising an n-type semiconductor, and the optically sensitive material having a work function; circuitry configured to apply a bias voltage between the first contact and the second contact; the magnitude of the work function of the optically sensitive material being at least about 0.4 eV less than the magnitude of the work function of the first contact, and also at least about 0.4 eV less than the magnitude of the work function of the second contact; circuitry configured to apply a bias voltage between the first contact and the second contact; and the optically sensitive material configured to provide a responsivity of at least about 0.8 A/W when the bias is applied between the first contact and the second contact.

The work function of the first contact and the second contact of the device of an embodiment are each deeper than about 4.5 eV.

The bias of the device of an embodiment is in the range of about 0.1 Volts to about 2.8 Volts.

The optically sensitive material of the device of an embodiment comprises nanoparticles selected from the group consisting of PbS, PbSe, PbTe, CdS, CdSe, CdTe, Si, Ge, or C.

The optically sensitive layer of the device of an embodiment comprises a material selected from the group consisting of PbSO₄, PbO, PbSeO₄, PbT eat, SiOₓN_{y}, In2O3, sulfur, sulfates, sulfoxides, carbon, and carbonates.

The first contact and the second contact of the device of an embodiment each comprise a material selected from the group consisting of Au, Pd, Pt, Ag, In, Cu, Ni, NiS, NiSi, Pt Si, TiN, or TaN.

The first contact and the second contact of the device of an embodiment are separated by a distance in the range of about 200 nm to about 2 μm and the hole mobility in the optically sensitive material is at least about 1E-5 cm²/Vs.

In embodiments, the device enables a feature referred to herein as “global shutter,” in which under appropriate biasing of the device as discussed below, collection of photocurrent can be selectively turned on and off. The layers referenced in the following discussion correspond to those in the materials stack that is illustrated in FIG. 3 (e.g. ‘1,’ ‘2,’ ‘4,’ ‘8,’ ‘9’). During the “on” phase of global shutter, in embodiments a bias can be applied across the stack such that a positive voltage is applied to the ‘material 1’ side of the stack and a negative voltage is applied to the ‘material 9’ side of the stack. When light is absorbed in ‘material 4,’ electron-hole pairs are generated. The bias across the stack causes the transit of electrons to the more positive electrode, ‘material 1,’ and holes toward the more negative electrode, ‘material 9,’ which results in photocurrent that can be detected by a read-out integrated circuit and used to generate a digital image.

In embodiments, the stack can also be turned “off,” with the appropriate biasing as discussed below. Referring to the layers in FIG. 3, in embodiments the speed with which the electrons and holes transit light absorbing layer, ‘material 4,’ can depend strongly on the electric field in ‘material 4.’ In embodiments, the electric field in ‘material 4’ can depend non-linearly on the voltage bias across the stack, such that with a large bias, for example >1 V, the electric field in ‘material 4’ can be large enough to quickly transport all electrons and holes out of ‘material 4,’ generating photocurrent. In this scenario, the stack is considered “on.” In embodiments, when the bias across the stack is smaller, for example <1V, there is much less electric field in ‘material 4,’ such that electrons and holes transit ‘material 4’ very slowly . When they transit ‘material 4’ so slowly, their recombination lifetime can be much less than the transport time, such that the photocurrent is reduced to near zero. In this state, the stack is considered “off,” because no photocurrent is collected at the electrodes.

The shutter efficiency can be defined as the ratio of photocurrent when the stack is biased such that it is “on” to the photocurrent when the stack is biased such that it is “off.” In embodiments, the shutter efficiency can be >100 dB.

Referring to the layers in FIG. 3, in embodiments “global shutter” can be achieved by alternating the bias applied to ‘material 9’ to toggle the device from the “on” state to the “off” state. A bias is applied to ‘material 9’ such that the device is “on” for a fixed amount of time. During this time, photocurrent can be collected at the electrode of ‘material 1.’ At the end of this time, the bias of ‘material 9’ can be rapidly changed such that the device is in the “off” state. In the “off” state, photocurrent is no longer collected at the electrode of ‘material 1,’ and the conversion of light to a digital signal has been halted. In the “off” state, the signal read out by the image sensor is insensitive the light incident upon it.

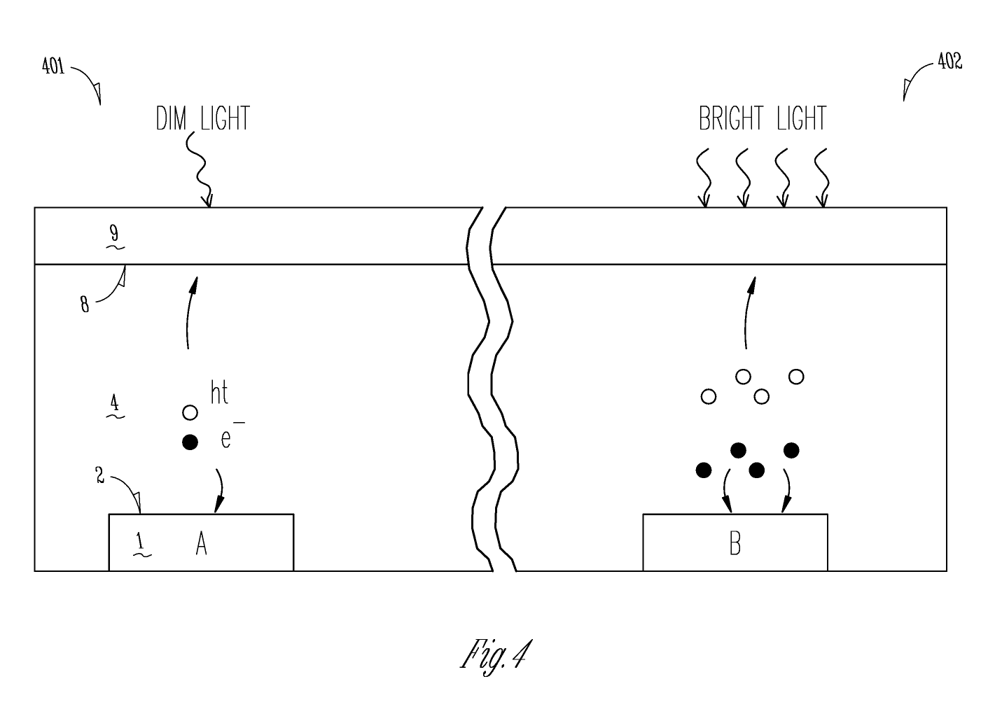

In embodiments, the appropriate choice of stack materials (FIG. 3) can substantially change the range of biases over which the stack is in the “off” state. For embodiments where the stack is connected with a read-out integrated circuit for use as an image sensor, it can be important that the range of biases over which the stack is in the “off” state be large. This is because in some embodiments of image sensors, the bias of one electrode is used to signal the magnitude of the photocurrent being generated, by integrating the collected photogenerated charge. In embodiments where photogenerated electrons transit ‘material 9’ toward ‘material 1,’ the voltage of ‘material 1’ begins at a more positive value, and is reduced to a lower value with the collection of electrons. An example of such an embodiment is shown in FIGS. 5, which shows the voltages of ‘material 9’ (V₉) and ‘material 1’ (V₁) over time for two different pixels, where the labeling of the materials corresponds to that of FIG. 3. Pixel A is illuminated with dim light, while Pixel B is illuminated with bright light. Under brighter light, the photocurrent becomes larger, and the voltage of ‘material 1,’ is reduced in a shorter amount of time. Put another way, for a given amount of time when the stack is in the “on” state, a brighter light will cause the voltage of ‘material 1’ to be lower (less positive), than a dim light or no light. In embodiments, a “bright light” can be one where the voltage of ‘material 1’ changes by >1 V during the “on” period, and has a photon flux of ˜8×10¹² cm ⁻² s⁻¹. In embodiments, a “dim light” can be one where the voltage of ‘material 1’ changes by <0.25 V during the “on” period, and has a photon flux of ˜2×10¹² cm⁻²s⁻¹.

In embodiments with image sensors, ‘material 1’ of FIG. 3 can be patterned into two or more individual pixels, such that an image can be spatially resolved. This is shown schematically in FIG. 4, which shows a cross-section of an embodiment with two pixels. The labeling of the materials in the stack of FIG. 4 (e.g. ‘1,’ ‘2,’ ‘4,’ ‘8,’ ‘9’) corresponds that of FIG. 3. The two pixels, which are not necessarily adjacent to each other within an array of pixels, are exposed to different amounts of light. In FIG. 4, the left side (including Pixel A) is exposed is exposed to dim light, and corresponds to curve A in FIG. 5, while the right side (including Pixel B) is exposed to bright light, and corresponds to curve B in FIG. 5. In such embodiments, ‘material 9’ can be un-patterned such that it is common to all of the pixels in the array . In such embodiments, the voltages of each pixel composed of ‘material 1’ can be independent, while the voltage of ‘material 9’ can be common to all the pixels.

In embodiments, the electric field in ‘material 4’ is generated by biasing independent features of the same layer. In embodiments, ‘material 1’ can be patterned into one or more features, and one feature is biased positively while a neighboring feature is biased negatively. The relative bias of the two features may be toggled to turn the device from the “on” to “off” states.

In embodiments with image sensors imaging a high dynamic range scene, the pixels made from ‘material 1’ can have a range of voltages at the end of a fixed integration time. Pixels exposed to a bright part of the image, which produces a lot of photocurrent, can have a more negative voltage than pixels exposed to a dim part of the image, which produces very little (or no) photocurrent. At the end of the integration period, the voltage of ‘material 9’ can be changed in order to switch the device from the “on” to the “off” state. When an image sensor has such a range of pixel voltages at the end of the integration period, there is no single, common voltage that can be applied to ‘material 9’ such that there is zero bias between ‘material 9’ and all independent pixels formed by ‘material 1.’

An example of this is illustrated in FIG. 5. At the beginning of the “on” period, both pixels A and B begin with a ‘material 1’ voltage (V₁) of 1.0 V. Pixel B sees bright light, while pixel A sees only dim light. At the end of the “on” period, pixel B has collected a large number of photogenerated electrons, such that its voltage has dropped to 0.0 V. By contrast, pixel A was in dim light, and has collected only a small number of photogenerated electrons; its voltage has dropped very little and is 0.75 V. The voltage of ‘material 9’ to turn the device “off” has been chosen to be 0.0V, in FIG. 5A. When the voltage of ‘material 9’ is switched to be 0.0 V, the voltage across pixel B, the bright pixel, will be ΔV_{B}=V_{1B}−V₉=0.0 V−0.0 V=0.0 V, such that pixel B is perfectly in the “off” state. By contrast, the bias across pixel A, the dim pixel, will be ΔV_{A}=V_{1A}−V₉=0.75 V−0.0 V=0.75 V, such that pixel A still has a driving force for the collection of photogenerated electrons at ‘material 1’; it may not be perfectly “off”

On the other hand, in the example of FIG. 5 if the voltage of ‘material 9’ is chosen such that it matches the voltage of the dim pixel (pixel A), then the dim pixel will be perfectly “off” but the bright pixel can still have a bias driving the collection of photocurrent. In the example of FIG. 5B, the voltage of ‘material 9’ during the “off” phase is chosen to be 0.75 V. Now the bias across pixel A, the dim pixel, will be ΔV_{A}=V_{1A}−V₉=0.75 V−0.75 V=0.0 V, and pixel A will be perfectly “off.” By contrast, the bias across pixel B, the bright pixel, will be ΔV_{B}=V_{1B}−V₉=0.0 V−0.75 V=−0.75 V; pixel B now has a bias such that it can collect photogenerated holes, and may not be perfectly “off.”

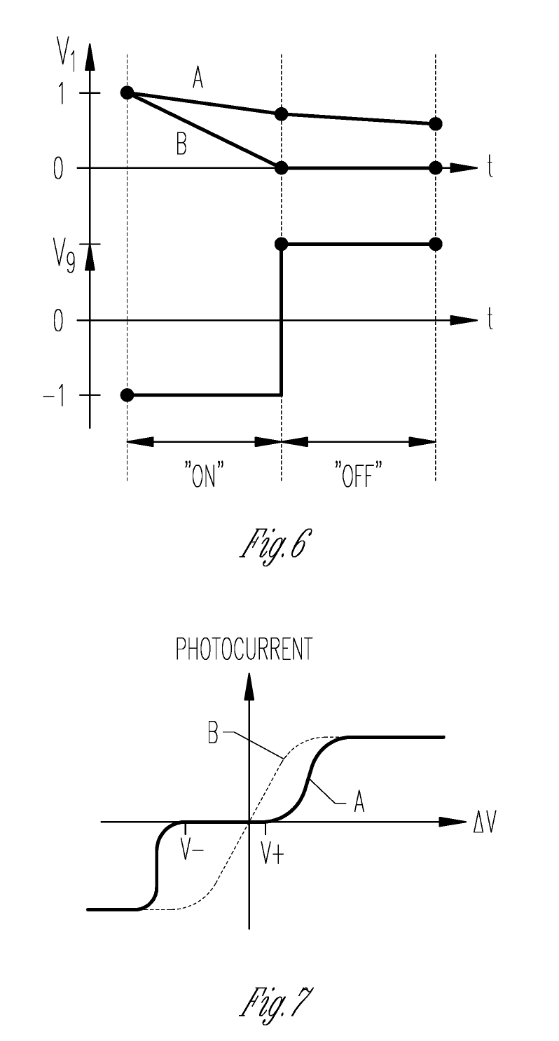

In embodiments, the device is engineered such that the collection of photocurrent is close to zero for a wide range of biases across the device. In embodiments with a high dynamic range image, this will allow bright and dim pixels to both be turned “off” with a high shutter efficiency for a single common choice of voltage applied to ‘material 9.’ This is illustrated in FIG. 7, which shows photocurrent vs. voltage curves for two different embodiments. The voltage on the x-axis of in FIG. 7 (ΔV), is the difference in potentials between ‘material 1’ and ‘material 9’ of FIG. 3 (ΔV=V₁−V₉). The device of curve B shows only a single bias for which the photocurrent is zero (ΔV=0 V). For this embodiment, any pixel that does not have 0 V bias across it can have substantial photocurrent collection. For such embodiments, a good circuit to read out the generated photocurrent is one where the voltage of the pixel does not change as photocurrent is collected. However, in embodiments where the voltage of the pixel does change with photocurrent collection, such as that illustrated in FIG. 5, not all of the pixels of a high dynamic range image will be “off.” By contrast, the device of curve A in FIG. 7 shows that the photocurrent is near zero for a wide range of biases (V₊ to V₋); this embodiment is said to have a “wide flat region” in its photocurrent vs voltage curve. In embodiments where the voltage of the pixel changes as photocurrent is collected, the device in this embodiment can support a high dynamic range image and still have all the pixels be “off” Such an embodiment can support a range of pixel voltages equal to (V₊-V₋), which is the width of the flat region in FIG. 7. In embodiments, the photocurrent across the range of biases (V₊-V₋) can be up to 100 dB less than the maximum photocurrent, such that all pixels in the array have a shutter efficiency of >100 dB.

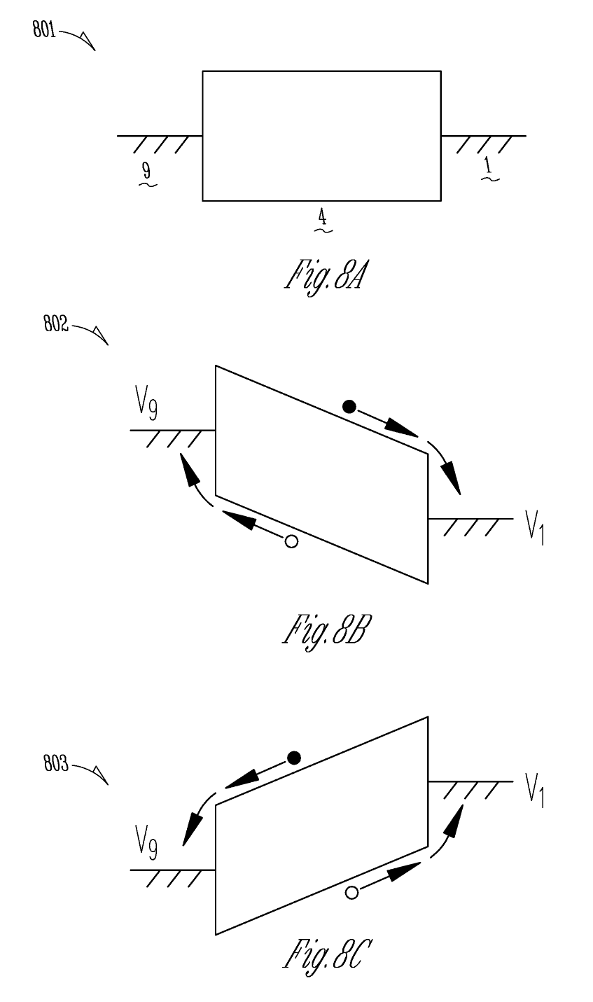

In embodiments with a wide flat region in the photocurrent-voltage curve, the device is engineered by the appropriate choice of electrodes and interfacial materials. Referring to the layers in FIG. 3, in embodiments where ‘material 8’ and ‘material 2,’ the two layers interfacing with the light absorbing layer ‘material 4,’ are metals, both electrons and holes can be easily collected at each electrode. This is shown schematically in FIG. 8, which shows an energy band diagram for such an embodiment. The materials in FIG. 8 are labeled to correspond with those in FIG. 3. FIG. 8A shows an embodiment in equilibrium (under zero applied bias), FIG. 8B shows an embodiment biased to be “on” (V₁>V₉) such that electrons are collected at ‘material 1’ and holes at ‘material 9,’ and FIG. 8C shows an embodiment biased such that electrons will be collected at ‘material 9’ and hole at ‘material 1’ (V₁<V₉). In such embodiments, the photocurrent vs voltage characteristics will resemble those of curve B in FIG. 7, which shows no flat region. Such an embodiment can show good shutter efficiency for all pixels when paired with a readout circuit in which the pixel voltage does not change as photocurrent is collected. In embodiments where the pixel voltage does change as photo current is collected, such an embodiment will show good shutter efficiency in global shutter operation for low dynamic range images, such that all the pixels in the image have similar voltages.

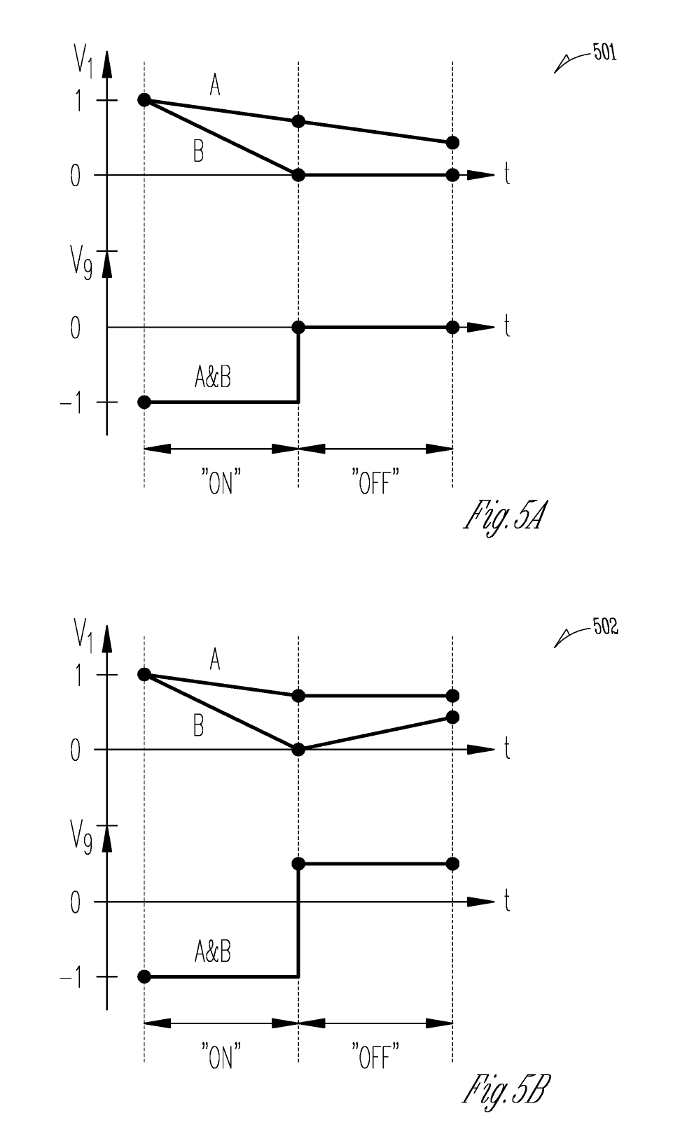

In embodiments where ‘material 2’ of FIG. 3 is a good hole blocker, the photocurrent voltage curve can achieve a wide flat region, such as is shown by curve A in FIG. 7. Such an embodiment can have a high shutter efficiency in global shutter mode even for high dynamic range images where there is a large difference in the voltages of the pixels in the array . This is illustrated in FIG. 6, which shows the voltages of ‘material 1’ and ‘material 9’ versus time for the for two pixels under different illumination conditions. Materials ‘1’ and ‘9’ in FIG. 6 are labeled to correspond to the same layers in FIG. 3. The “off” phase voltage of ‘material 9’ can be chosen to match the highest possible voltage for a pixel; in this example embodiment, 1.0V. Now when the device is turned “off” at the end of the “on” period, there is a bias for both pixels A and B that will drive photogenerated holes toward ‘material 1.’ The bias across pixel A is ΔV_{A}=V_{1A}−V₉=0.75 V−1.0 V=−0.25 V, and the bias across pixel B is ΔV_{B}=V_{1B}−V₉=0 V−1.0 V=−1.0 V. However, if the flat region of the photocurrent vs voltage curve extends all the way to ΔV=−1.0 V, then there will be very little hole collection at ‘material 1’ of both pixels A and B, in spite of the bias. Thus the wide flat region enables pixels in a high dynamic range image to all be “off.”

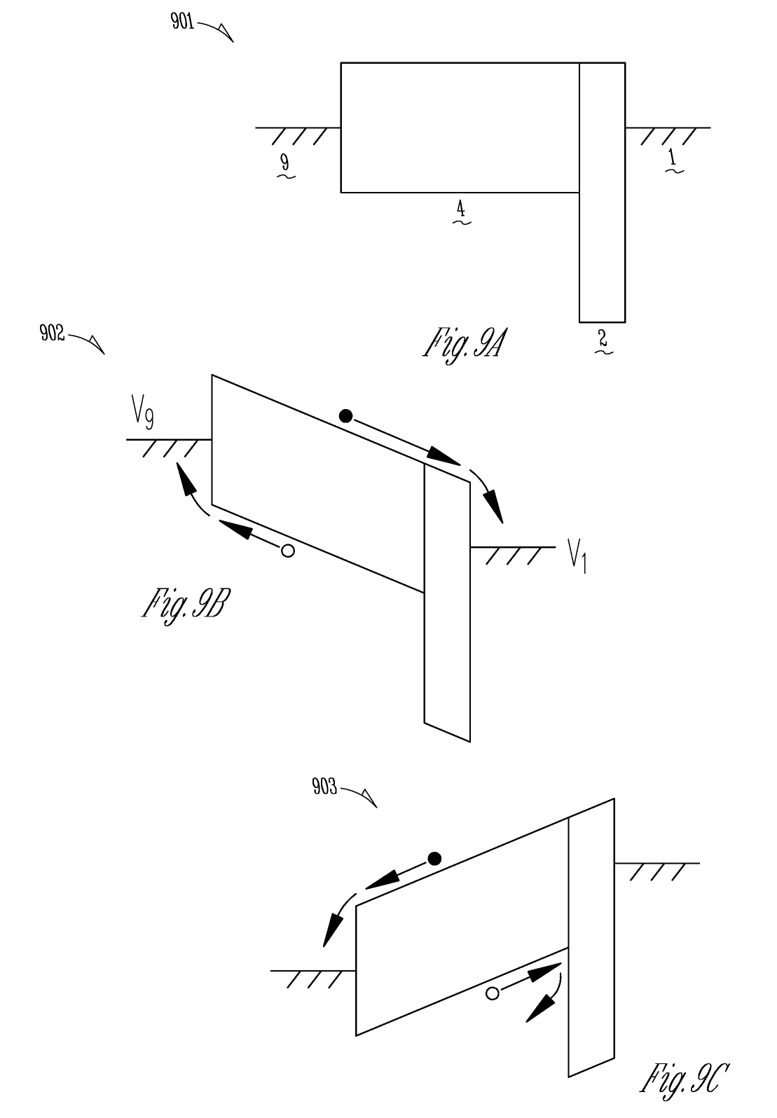

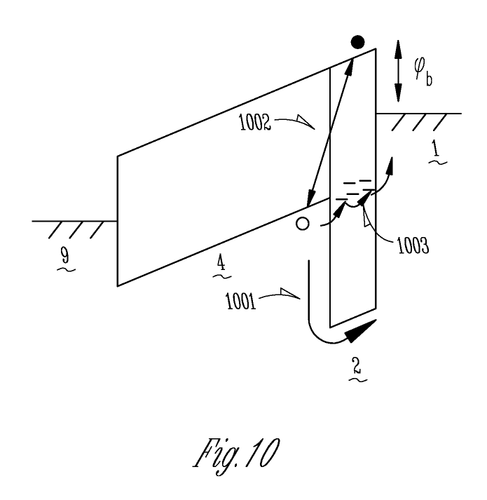

FIG. 9 shows an energy band diagram for an embodiment where ‘material 2’ is a good hole blocker. The layers in FIG. 9 are labeled to correspond to those in FIG. 3. FIG. 9A shows an embodiment in equilibrium, FIG. 9B shows an embodiment biased such that is it “on” and electrons are collected at ‘material 1,’ and FIG. 9C shows an embodiment biased such that it is “off,” and neither electrons nor holes are collected at ‘material 1.’

In embodiments, a wide flat region can be obtained because ‘material 2’ is an impediment to hole collection at ‘material 1.’ In such embodiments, there can be three mechanisms for hole transfer through ‘material 2,’ when a bias is applied such that holes are driven toward ‘material 1.’ Embodiments of these three mechanisms are illustrated in FIG. 10 (1001, 1002, 1003). In embodiments with a high global shutter efficiency, it is desirable for all three mechanisms to be as slow as possible. The layers in FIG. 10 (‘1,’ ‘2,’ ‘4,’ ‘9’) are labeled to correspond to those in FIG. 3, and are biased with V₁<V₉, such that there is a driving force for hole collection at ‘material 1.’

Referring to FIG. 10, mechanism 1001 is the thermionic emission of holes into the valence band of the hole blocking layer, ‘material 2.’ If the valence band edge is much deeper than the valence band edge of the light absorbing layer, ‘material 4,’ then this mechanism for hole transfer can be very slow. This is illustrated in to FIG. 10, which shows a large valence band edge offset between ‘material 4’ and ‘material 2.’ In such embodiments, the flat region of the photocurrent voltage curve can be very wide.

Referring to FIG. 10, in mechanism 1002 holes are collected through ‘material 2’ by recombination with electrons in ‘material 2.’ If there are very few electrons in the conduction band of ‘material 2,’ then this process can be slow. In such embodiments ‘material 2’ is an effective hole blocker, and the photocurrent vs voltage curve can have a wide flat region. The electrons in ‘material 2’ can come from two sources. Firstly, if ‘material 2’ is n-type doped, there is a readily available equilibrium population of electrons in its conduction band, which can recombine with the photogenerated holes in ‘material 4.’ Thus in embodiments, a good hole blocker can be fully depleted, such that the electron density in its conduction band is low. In order to be fully depleted, ‘material 2’ can be either thin, or lightly doped. For example, if ‘material 2’ is 10 nm thick, then it can have a free electron density <1×10¹⁹ cm⁻³. Secondly, the electrons in the conduction band of ‘material 2’ can be injected from ‘material 1.’ The rate of such injection is controlled by the energy difference between the work function of ‘material 1,’ and the conduction band edge of ‘material 2.’ This is given by φ_{b} in FIG. 10, and the rate of injection will be governed by thermionic emission or Fowler-Nordheim tunneling, depending on the energy barrier and the local electric field. If this energy barrier is large, this mechanism can be slow, and ‘material 2’ can be an effective hole blocker. In such embodiments, the photocurrent vs voltage curve can have a wide flat region.

In such embodiments, the work function of ‘material 1’ can be >4.5 eV below vacuum, in order to make the barrier for injection of electrons (φ_{b} in FIG. 10) large.

Referring to FIG. 10, in Mechanism 1003, holes are conducted through ‘material 2,’ either by direct tunneling or via a continuous band of occupied traps. In embodiments, the direct tunneling rate can be inversely proportional to the thickness of the hole blocking layers, such that increasing the thickness of the hole blocker decreases the extraction rate of holes by direct tunneling. In some embodiments there is a significant trap density in the hole blocker, and hole traps are close in space and close in energy such that holes can hop from trap to trap through the entire thickness of this film. If ‘material 2’ does not have very many traps, or if these traps are highly delocalized in energy, or if the thickness of ‘material 2’ is large enough, then the hopping of holes through the traps can be very slow, and ‘material 2’ can be an effective hole blocker. In such embodiments, the photocurrent vs voltage curve can have a wide flat region.

In embodiments with an effective hole blocker, all three of these mechanisms can be slow. In embodiments, “slow” is determined by the intensity of light incident upon the device. If the shutter efficiency is to exceed 100 dB, then the rate of hole transfer through ‘material 2’ must be 100 dB less than the rate of photon incidence upon the device. For example, if a light intensity equivalent to 5440 photons/s is incident on the device, then one photon is transported through ‘material 4’ to the interface with ‘material 2’ every ˜18 μs. For the shutter efficiency to exceed 100 dB, the time for hole extraction through ‘material 2’ must be greater than 10̂ (100/20)*18 μs, which is >18 s. If the light intensity is higher than this, then the requirement for good shutter efficiency is relaxed. For example, if a light intensity equivalent to 544,000 photons/s is incident on the device, then the time for hole extraction must be >0.18 s in order to have a shutter efficiency >100 dB. In such embodiments, the time for hole extraction for all three mechanisms independently can be greater than this time to achieve such shutter efficiencies.

In embodiments where ‘material 1’ is patterned into individual pixels to form an imaging array, the hole blocking ‘material 2’ can also be patterned into pixels. This is particularly important if the conductivity of ‘material 2’ is high enough to short the pixels together. In embodiments, the patterning of ‘material 2’ into individual pixels can be accomplished by masking and lithography. In embodiments, it can be accomplished by forming ‘material 2’ from a previously patterned layer, for example, by the oxidation of previously patterned TiN to form TiO₂ or TiOₓN_{y}.

In embodiments where ‘material 2’ is a good hole blocker, it can simultaneously be a good conductor of electrons. This can allow the device to easily collect electrons at ‘material 1’ during the “on” phase of operation. In embodiments where there is rapid electron conduction, the conduction band of ‘material 2’ can be close to or lower than the conduction band of the light absorbing layer, ‘material 4.’ In such embodiments, there is no energy barrier for electron transmission through ‘material 2.’ In embodiments the electron mobility of ‘material 2’ can be high (>1×10⁻³ cm²/V-s), providing for the rapid conduction of electrons through ‘material 2.’

The following is a list of characteristics a good hole blocking material (‘material 2’) can have in such embodiments:

conduction band edge 0.5 eV above or below the conduction band edge of ‘material 4’

band gap energy greater than or the band gap energy of ‘material 4’

free electron density<1×10¹⁹ cm⁻³

electron mobility>1×10⁻⁵ cm²/V-s

film thickness 5-100 nm

hole trap density<1×10¹⁹ cm⁻³

In an example embodiment when the conduction band edge of ‘material 4’ is 4.0 eV below the vacuum level and the band gap of ‘material 4’ is 1.5 eV, a good hole blocking layer (‘material 2’) can have:

conduction band edge 3.5 eV to 4.5 eV below the vacuum level

band gap energy greater than 2.0 eV

free electron density<1×10¹⁷ cm⁻³

electron mobility>1×10⁻³ cm²/V-s

film thickness 5-20 nm

hole trap density<1×10¹⁷ cm⁻³

In embodiments, ‘material 2’ can be a very wide band gap semiconductor or insulator, such that from a band diagram perspective, it is a good hole blocker and also an electron blocker. In such embodiments, a wide flat region can be achieved by the hole blocking properties as described above. In such embodiments, ‘material 2’ can still be a good conductor of electrons, such that the photocurrent collection when the device is “on” is very efficient. Good conduction of electrons can happen by several different mechanisms. In some embodiments, good conduction of electrons though a wide band gap insulator can be accomplished by tunneling under a large electric field. When the device is in the “on” state, the applied bias across the device can be >1V. The electric field driving tunneling of electrons through ‘material 2’ can be approximately found by dividing the applied bias by the total thickness of ‘material 2,’ and ‘material ‘4, and can be >1×10⁴ V/cm. By contrast, when the device is “off,” the applied bas across the device can be <1V. The electric field driving tunneling of electrons or holes to through ‘material 2’ can be <1×10⁴ V/cm. In such embodiments, the tunneling rate of electrons and holes through ‘material 2’ can be very different under different electric fields, such that the device can have a global shutter efficiency >100 dB.

In embodiments where ‘material 2’ is a very wide band gap semiconductor or insulator, good conduction of electrons through ‘material 2’ can occur by rapid tunneling or hopping through ‘material 2’ even under small electric fields. In embodiments, tunneling of electrons through ‘material 2’ can be fast for low thicknesses of ‘material 2,’ for example, <3 nm. In other embodiments, transport of electrons through ‘material 2’ can be aided by electron hopping through a distribution of trap states. In such embodiments, the conduction of electrons through ‘material 2’ can be very efficient, even if the band diagram shows a large conduction band offset that would otherwise inhibit electron conduction. In such embodiments, the conduction of holes through ‘material 2’ can still be very slow, such that ‘material 2’ is a good hole blocker, and the device can have a global shutter efficiency >100 dB.

In embodiments when ‘material 2’ is a hole blocker, it can be a deposited layer, and can include oxides, nitrides, sulfides or oxynitrides of aluminum, gallium, indium, tin, lead, bismuth magnesium, calcium, zinc, molybdenum, titanium, vanadium, lanthanum, chromium, manganese, iron, cobalt, nickel, copper, zirconium, niobium, palladium, silver, hafnium, tantalum, tungsten, iridium, platinum, gold. In embodiments, it can be preferred that it include oxides, nitrides, or oxynitrides of metals used in standard CMOS such as aluminum, tungsten, tantalum, titanium, copper. In embodiments, these oxides can be sub-stoichiometric, such that they are somewhat oxygen deficient, such as TiO₂₋ₓ.

In embodiments, when ‘material 2’ is a hole blocker, it can be deposited by atomic layer deposition, sputter deposition, pulsed laser deposition, chemical vapor deposition, plasma enhanced chemical yap or deposition, thermal evaporation, electron beam evaporation, or by solution processing techniques, such as spin coating, dip coating, doctor blading slot-die coating electrochemical deposition.

In embodiments, when ‘material 2’ is a hole blocker, it can be a layer formed from the surface of a metal, and can include oxides, nitrides, sulfides, or oxynitrides of aluminum, gallium, indium, tin, lead, bismuth magnesium, calcium, zinc, molybdenum, titanium, vanadium, lanthanum, chromium, manganese, iron, cobalt, nickel, copper, zirconium, niobium, palladium, silver, hafnium, tantalum, tungsten, iridium, platinum, gold. In embodiments, it can be preferred that it include oxides, nitrides, or oxynitrides of metals used in standard CMOS such as aluminum, tungsten, tantalum, titanium, copper.

In embodiments, when ‘material 2’ is a hole blocker, it can be a semiconducting polymer, including functionalized conjugated groups including thiophenes, carbazoles, vinylenes, azides, isoindigos, such as P3HT, MEH-PPV, PCDTBT, F8TB.

In embodiments, when ‘material 2’ is a hole blocker, it can be a semiconducting organic small molecule, such as Alq3, BCP, Spiro-OMeTAD, CuPc.

In embodiments, when ‘material 2’ is a hole blocker, it can be a metal-organic perovskite, such as those containing metal halides. These can include, methyl ammonium lead iodide, methyl ammonium lead chloride, methyl ammonium tin iodide.

In embodiments, an electron blocking layer can enhance the ability of the hole blocking layer to improve global shutter efficiency . Whereas a hole blocking layer can be added as ‘material 2’ to slow the extraction of holes toward ‘material 1,’ an electron blocking layer can be added as ‘material 8’ to slow the extraction of electrons toward ‘material 9.’ In embodiments, the global shutter efficiency can be higher if the rate of carrier extraction at ‘material 1’ is equal to that at ‘material 9’ when the device is in the “off” state. In such embodiments there can be no build up of charge due to unequal extraction of electrons and holes from the device on short time scales. In embodiments where the device is rapidly toggled between the “on” and “off” states, a device with no build up of charge have better lag and hysteresis than one with a large build up net charge. An electron blocker can have properties analogous to a hole blocker, except that the electron blocker can slow the collection of electrons at ‘material 9’ while permitting the rapid collection of holes at ‘material 9.’

In embodiments, an electron blocker can have the following properties:

valence band edge 0.5 eV above or below the valence band edge of ‘material 4’

band gap energy greater than or the band gap energy of ‘material 4’

free hole density<1×10¹⁹ cm⁻³

hole mobility>1×10⁻⁵ cm²/V-s

film thickness 5-100 nm

electron trap density<1×10¹⁹ cm⁻³

In an example embodiment when the valence band edge of ‘material 4’ is 5.2 eV below the vacuum level and the band gap of ‘material 4’ is 1.5 eV, a good electron blocking layer (‘material 8’) can have:

valence band edge 4.7-5.7 eV below vacuum

band gap energy>2 eV

free hole density<1×10¹⁷ cm⁻³

hole mobility>1×10⁻³ cm²/V-s

film thickness 5-20 nm

electron trap density<1×10¹⁷ cm⁻³

In embodiments, when ‘material 8’ is an electron blocker, it can be a deposited layer, and can include oxides, nitrides, sulfides or oxynitrides of aluminum, gallium, indium, tin, lead, bismuth magnesium, calcium, zinc, molybdenum, titanium, vanadium, lanthanum, chromium, manganese, iron, cobalt, nickel, copper, zirconium, niobium, palladium, silver, hafnium, tantalum, tungsten, iridium, platinum, gold. In embodiments, it can be preferred that it include oxides, nitrides, or oxynitrides of metals used in standard CMOS such as aluminum, tungsten, tantalum, titanium, copper. In embodiments, these oxides can be sub-stoichiometric, such that they are somewhat oxygen deficient, such as TiO₂₋ₓ.

In embodiments, when ‘material 8’ is an electron blocker, it can be deposited by atomic layer deposition, sputter deposition, pulsed laser deposition, chemical vapor deposition, plasma enhanced chemical vapor deposition, thermal evaporation, electron beam evaporation, or by solution processing techniques, such as spin coating, dip coating, doctor blading slot-die coating electrochemical deposition.

In embodiments, when ‘material 8’ is an electron blocker, it can be a layer formed from the surface of a metal, and can include oxides, nitrides, sulfides or oxynitrides of aluminum, gallium, indium, tin, lead, bismuth magnesium, calcium, zinc, molybdenum, titanium, vanadium, lanthanum, chromium, manganese, iron, cobalt, nickel, copper, zirconium, niobium, palladium, silver, hafnium, tantalum, tungsten, iridium, platinum, gold. In embodiments, it can be preferred that it include oxides, nitrides, or oxynitrides of metals used in standard CMOS such as aluminum, tungsten, tantalum, titanium, copper.

In embodiments, when ‘material 8’ is an electron blocker, it can be a semiconducting polymer, including functionalized conjugated groups including thiophenes, carbazoles, vinylenes, azides, isoindigos, such as P3HT, MEH-PPV, PCDTBT, F8TB.

In embodiments, when ‘material 8’ is an electron blocker, it can be a semiconducting organic small molecule, such as Alq3, BCP, Spiro-OMeTAD, CuPc.

In embodiments, when ‘material 8’ is an electron blocker, it can be a metal-organic perovskite, such as those containing metal halides. These can include, methyl ammonium lead iodide, methyl ammonium lead chloride, methyl ammonium tin iodide.

In embodiments, the device operates such that on the “on” state electrons are collected at ‘material 1’ and holes are collected at ‘material 9.’ In such embodiments, ‘material 2’ can be a hole blocker and ‘material 8’ can be an electron blocker. In other embodiments the device operation can be reversed, such that in the “on” state holes are collected at ‘material 1’ and electrons are collected at ‘material 9.’ In such embodiments, ‘material 2’ can be an electron blocker and ‘material 8’ can be a hole blocker. In such embodiments, the device can achieve a global shutter efficiency can be >100 dB.

In embodiments, the toggling of the voltage of ‘material 9’ (referring to the stack in FIG. 3) to turn the device from the “on” state to the “off” state, or vice versa, can couple some of the voltage to ‘material 1.’ The amount of voltage coupled from ‘material 9’ to ‘material 1’ can depend on the relative capacitance of the stack shown in FIG. 3, and the capacitance of the rest of the readout circuit. In embodiments where the readout of the photocurrent signal does not depend on the voltage of ‘material 1,’ this coupling may not affect the signal. In embodiments where the readout of the photocurrent depends on the voltage of ‘material 1,’ such as the example given in FIG. 5, this coupling can affect the readout signal.

In embodiments where the coupling of the voltages of materials ‘9’ and ‘1’ is identical when the device is toggled from “on” to “off” as when it is toggled from “off” to “on,” there can be no effect on the readout signal. This is because the device can be toggled from “off” to “on” and back to “off” again before readout, thus completely undoing the effect of the coupling

In embodiments where the capacitance of one or more of the layers in the stack of FIG. 3 changes with time, bias, or light exposure, the amount of voltage coupled between ‘material 9’ and ‘material 1’ can be different when the device is toggled from “on” to “off” than when it is toggled from “off” to “on.” In embodiments where the readout photocurrent depends on the voltage of ‘material 1,’ this can cause an imaging artifact or non-linearity . In such embodiments, the imaging artifact can be mitigated by making the capacitance of the readout circuit much greater than the capacitance of the stack in FIG. 3. In such embodiments, the voltage coupling from ‘material 9’ to ‘material 1’ can be largely independent of the capacitance of the stack in FIG. 3. In such embodiments, even if the capacitance of the stack in FIG. 3 changes with time, bias, or light exposure, it will not affect the readout signal.

In embodiments where the readout of the photocurrent depends on the voltage of ‘material 1,’ an imaging artifact due to the coupling of voltage from ‘material 9’ to ‘material 1’ can be mitigated by minimizing the change of the capacitance of the all the materials in the stack of FIG. 3 with time, bias, or light exposure. In order to minimize such a change in capacitance, the extraction of both electrons and holes from the materials stack can be very fast, such that there is no build up of charge in the stack. In such embodiments, the electron and hole mobilities of each of the materials in FIG. 3 can be >1×10⁻⁴ cm²/V-s. In such embodiments, there can be no energetic barriers for the extraction of electrons and holes, such as an offset of conduction or valence band energies between two adjacent materials. In such embodiments, the coupling of voltage from ‘material 9’ to ‘material 1’ can be the same when the device is toggled from “on” to “off” as it is when toggled from “off” to “on,” such that there is no imaging artifact introduced by the coupling.

In embodiments time-lag related imaging artifacts can occur when carrier trapping in any of the stack materials is significant. In embodiments, electrons or holes can become deeply trapped in the device under illumination, and de-trap at a later time, producing a an after-image or lag artifact. In embodiments, the after-image can appear as a positive after-image (a faint copy of earlier frames) or a negative after-image (an inverse intensity copy of earlier frames, where formerly bright areas appear dark and formerly dark areas appear bright). In embodiments, carrier trapping can occur to different degrees depending on the bias applied to the device. In embodiments where the device is operating in global shutter mode, such that the device is toggling between “on” and “off” states, the after-image can look discretized and highly localized in space. For example, in embodiments where carriers become trapped when the device is in the “off” state, the after image can be generated for pixels that are in the “off” state when a bright light was shined on them. In other embodiments where carriers become trapped when the device is in the “on” state, the after image can be generated for pixel that are in the “on” state when a bright light was shined on them, while other pixels may produce no after image.

In embodiments, time-lag imaging artifacts can be minimized by reducing the number or depth of trap sin all the materials in the stack (e.g. ‘material 2,’ ‘material 4,’ ‘material 9’). The number of traps can be reduced by obtaining high quality and pure materials, and by processing the materials in a way that minimizes inclusions, voids, dangling bonds, and/or the area of hetero-interfaces. In embodiments, ‘material 1’ can be an electrode made from titanium nitride (TiN). In embodiments, the TiN layer can be deposited of otherwise formed by chemical yap or deposition, physical yap or deposition, thermal evaporation, or electrochemical deposition. The TiN layer can be patterned into an array of individual electrodes, where there is an insulating material in between adjacent TiN pads, such that each TiN pad is electronically isolated. In embodiments, the TiN pads can be very uniform in size, shape, and spacing, such that each individually defined pixel has the same TiN coverage. In such embodiments, the dark current and photo-response non-uniformity of photodetectors based on such arrays can be very low, <0.1%.

In embodiments where the TiN is patterned into individual electrodes (pads), the size of the TiN electrode can be varied to change properties of the photo-sensor device. The TiN electrode dimension can be large, such that its width is nearly the pitch between adjacent TiN electrodes and the TiN layer is nearly continuous. In such embodiments, the electric field created by applying a bias between ‘material 1’ and ‘material 9’ will be very uniform throughout the intervening layers (materials 2-8), pointing vertically from ‘material 9’ to ‘material 1.’ In such embodiments, the drift velocity of photogenerated carriers in ‘material 4’ will be the same, regardless of where they are generated, since the electric field is uniform.

In other embodiments, the TiN electrode can be very small, such that it fills <10% of the surface area (e.g., 90% of the area has no TiN). In such embodiments, the electric field created by applying a bias between ‘material 1’ and ‘material 9’ can be non-uniform throughout materials ‘2’ through ‘8.’ In such embodiments, directly above a TiN pad the electric field can be strongest, while in between TiN pads (where the TiN has been removed by patterning), the electric field can be weaker. In such embodiments, the drift velocity of photogenerated charges can be higher directly above the TiN pads than in the sp ace between them, because of the non-uniform electric field. In such embodiments, there can be zones in between the defined TiN pads where the collection efficiency of photogenerated carriers is near zero.

In some embodiments, this non-uniform electric field created by a small TiN electrode can be used to tune the collection of photogenerated carriers to affect how many of them are collected at a given bias. In such embodiments, different colors of light can be collected with different efficiencies, since different photon colors can be absorbed at different locations in ‘material 4,’ and therefore photogenerate carriers with different drift velocities.

In embodiments, the thickness of the TiN layer can be chosen such that the TiN layer is thick enough to be mechanically robust and have good adhesion to the underlying and above-lying layers. The thickness of the TiN layer can also affect the size of the TiN sidewall, after the TiN has been patterned into individual electrodes. The TiN electrode can be thin enough that subsequent layers deposited on top of it achieve uniform sidewall coverage. In general, thicker TiN layers make it more difficult to uniformly cover the sidewall during the deposition of subsequent layers, though this dep ends on the technique used to deposit the subsequent layers. In embodiments, the thickness of the TiN layer can be between 5 nm and 250 nm to ensure mechanical robustness and a sufficiently small sidewall that coverage of subsequent layers can be very good.

In embodiments, the TiN conductivity can be high enough such that there is no substantial voltage drop across the TiN electrode. In embodiments where the TiN resistance is <1 M Ohm, the voltage drop across it can be <10 mV. In embodiments, the conductivity of TiN can be much higher, such that the resistance of a TiN pad is <1 Ohm.

In embodiments, the composition of the TiN can be altered after its initial deposition by treatment of the TiN with plasma. In oxygen plasma or a plasma in which oxygen is a partial component, the TiN can form an oxide layer on top. In embodiments, the formation of this oxide layer can affect the properties of the electrode, including stoichiometry, electrical conductivity, work function, band gap, electron affinity, doping density, and trap density. In some embodiments, the TiN can be highly oxidized such that the layer formed on top of the TiN is nearly pure TiO2. In such embodiments, the TiN electrode can be a good hole blocking layer, since TiO2 can be a wide band gap semiconductor with very low trap density, whose doping density can be tuned as described above to make it a good hole blocking layer.

In other embodiments, the TiN can be only partially oxidized, such that the stoichiometry of the top of the TiN electrode can be TiOₓN_{y} (mixed oxide and nitride). In such embodiments, the relative ratios of N and O can be used to tune the doping density and conductivity of the TiN electrode, so that the electrode is sufficiently conductive so that there is no significant voltage drop across it, and that it can be a good electron collector and hole blocker.

In embodiments, the plasma treatment process applied to an electrode of TiN can embed other elements into the TiN layer, which can be used to alter the properties of the TiN. In embodiments where the TiN pads are surrounded by SiO₂, the plasma treatment process can cause the re-sputtering of Si from the nearby SiO₂ into the TiN electrode. The resulting composition of the TiN can contain Ti, O, N, Si. In such embodiments the amount of Si embedded in the TiN can affect its electrical conductivity. The parameters of the plasma treatment, including time, temperature, power, bias voltage and gas composition can be varied to tune the amount of Si that is embedded into the TiN. In embodiments with a high Si content, the TiN electrode can become more insulating. In such embodiments, the TiN can become a wide band gap insulator, such that it becomes a good hole blocking material. In embodiments, the Si content can also be kept sufficiently low so that the TiN does not become too resistive, and there is still good collection of the photogenerated charge when the device is in the “on” state.

In embodiments where the TiN is surrounded by other materials or where the plasma gas has a different composition, other elements can be chosen to be re-sputtered and embedded into the TiN. These include but are not limited to: silicon, oxygen, nitrogen, zinc, sulfur, fluorine, chlorine, molybdenum, aluminum, hydrogen, lithium, sodium, potassium, cadmium, and tungsten.

In embodiments, an electronic device includes at least one photosensitive layer and at least one carrier selective layer; wherein, under one range of biases on the device, the photosensitive layer produces a photocurrent while illuminated; wherein, under another range of biases on the device, the photosensitive does not produce a photocurrent while illuminated; and wherein, a carrier selective layer expands the range of biases over which the photosensitive layer does not produce any photocurrent while illuminated.

In embodiments, an image sensor providing global electronic shutter is disclosed. The image sensor includes an integrated circuit; a first charge-extracting layer; an optically sensitive layer; and a second hole-extracting layer; wherein, in a first mode (the ‘on’ mode), electrons are extracted via the first charge-extracting layer, and wherein, in a second mode (the ‘off’ mode), the extraction of holes is prevented by the first charge-extracting layer.

In various embodiments, the integrated circuit comprises silicon.

In various embodiments, the first charge-extracting layer comprises at least one material from the list of materials including TiO2, ZnO, Ta2O5, CuO, Cu2O, ZrO2, Nb2O5, HfO2, and TiOxNy.

In various embodiments, the first charge-extracting layer prevents the collection of holes by providing an energy barrier to hole collection by thermionic emission.

In various embodiments, the first charge-extracting layer prevents the collection of holes by being substantially fully depleted of electrons such that recombination of photo-generated holes with electrons in the first charge-extracting layer is slow.

In various embodiments, the first charge-extracting layer prevents the collection of holes by tunneling or trap-assisted tunneling through the first charge-extraction layer.

In various embodiments, the first charge-extracting layer can be patterned into electrically isolated pixels.

In various embodiments, the first charge-extracting layer can be a fast extractor of charge when ‘on.’

In various embodiments, the optically sensitive layer comprises at least one material from the list of materials including semiconducting polymer, semiconducting organic small molecule, quantum dots, and metal-organic perovskite semiconductor.

In various embodiments, the optically sensitive layer has an appropriate band alignment to the first charge-extracting layer to allow for good carrier collection when ‘on’ and poor hole extraction when ‘off.’

In various embodiments, the optically sensitive layer can have a low number of deep trap states such that charge is quickly extracted.

In various embodiments, the hole-extracting layer comprises at least one material from the list of materials including CoO, MoO3, WO3, NiO, ITO, AZO, and Spiro-OMeTAD.

In various embodiments, the integrated circuit can control the bias across the optically sensitive layer to turn a device stack from “on” to “off.”

In various embodiments, the off region can have a voltage width wide enough to include a full dynamic range of the image sensor.

In embodiments, an image sensor providing global electronic shutter is disclosed. The image sensor includes an integrated circuit, a first electrode, a first charge-extracting layer, an optically sensitive layer, and a second hole-extracting layer. In a first mode (the ‘on’ mode), electrons are extracted via the first charge-extracting layer into the first electrode. In a second mode (the ‘off’ mode), an injection of electrons is prevented via an energetic barrier between a first contact and the first charge-extracting layer.

In various embodiments, the integrated circuit comprises silicon.

In various embodiments, the first charge-extracting layer comprises at least one material from the list of materials including TiO2, ZnO, Ta2O5, CuO, Cu2O, ZrO2, Nb2O5, HfO2, and TiOxNy.

In various embodiments, the first charge-extracting layer prevents the collection of holes by providing an energy barrier to hole collection by thermionic emission.

In various embodiments, the first charge-extracting layer prevents the collection of holes by being substantially fully depleted of electrons such that recombination of photo-generated holes with electrons in the first charge-extracting layer is slow.

In various embodiments, the first charge-extracting layer prevents the collection of holes by tunneling or trap -assisted tunneling through the first charge-extraction layer.

In various embodiments, the first charge-extracting layer can be patterned into electrically isolated pixels.

In various embodiments, the first charge-extracting layer can be a fast extractor of charge when ‘on.’

In various embodiments, the optically sensitive layer comprises at least one material from the list of materials including semiconducting polymer, semiconducting organic small molecule, quantum dots, and metal-organic perovskite semiconductor.

In various embodiments, the optically sensitive layer has an appropriate band alignment to the first charge-extracting layer to allow for good carrier collection when ‘on’ and poor hole extraction when ‘off.’

In various embodiments, the optically sensitive layer can have a low number of deep trap states such that charge is quickly extracted.

In various embodiments, the hole-extracting layer comprises at least one material from the list of materials including CoO, MoO3, WO3, NiO, ITO, AZO, and Spiro-OMeTAD.

In various embodiments, the integrated circuit can control the bias across the optically sensitive layer to turn a device stack from “on” to “off.”

In various embodiments, the off region can have a voltage width wide enough to include a full dynamic range of the image sensor.

Unless the context clearly requires otherwise, throughout the description and the claims, the words “comprise,” “comprising,” and the like are to be construed in an inclusive sense as opposed to an exclusive or exhaustive sense; that is to say, in a sense of “including, but not limited to.” Words using the singular or plural number also include the plural or singular number respectively . Additionally, the words “herein,” “hereunder,” “above,” “below,” and words of similar import, when used in this application, refer to this application as a whole and not to any particular portions of this application. When the word “or” is used in reference to a list of two or more items, that word covers all of the following interpretations of the word: any of the items in the list, all of the items in the list and any combination of the items in the list.

The above description of embodiments is not intended to be exhaustive or to limit the systems and methods to the precise forms disclosed. While specific embodiments of, and examples for, the embodiments are described herein for illustrative purposes, various equivalent modifications are possible within the scope of the systems and methods, as those skilled in the relevant art will recognize. The teachings of the embodiments provided herein can be applied to other systems and methods, not only for the systems and methods described above.

The elements and acts of the various embodiments described above can be combined to provide further embodiments. These and other changes can be made to the embodiments in light of the above detailed description.

What is claimed is:

1. An image sensor providing global electronic shutter, the image sensor comprising:
an integrated circuit;
a first charge-extracting layer;
an optically sensitive layer; and
a second hole-extracting layer; wherein, in a first mode (the ‘on’ mode), electrons are extracted via the first charge-extracting layer, and wherein, in a second mode (the ‘off’ mode), the extraction of holes is prevented by the first charge-extracting layer.

2. The image sensor of claim 1, wherein the integrated circuit comprises silicon.

3. The image sensor of claim 1, wherein the first charge-extracting layer comprises at least one material from the list of materials including TiO2, ZnO, Ta2O5, CuO, Cu2O, ZrO2, Nb2O5, HfO2, and TiOxNy.

4. The image sensor of claim 1, wherein the first charge-extracting layer prevents the collection of holes by providing an energy barrier to hole collection by thermionic emission.

5. The image sensor of claim 1, wherein the first charge-extracting layer prevents the collection of holes by being substantially fully depleted of electrons such that recombination of photo-generated holes with electrons in the first charge-extracting layer is slow.

6. The image sensor of claim 1, wherein the first charge-extracting layer prevents the collection of holes by tunneling or trap-assisted tunneling through the first charge-extraction layer.

7. The image sensor of claim 1, wherein the first charge-extracting layer can be patterned into electrically isolated pixels.

8. The image sensor of claim 1, wherein the first charge-extracting layer can be a fast extractor of charge when ‘on.’

9. The image sensor of claim 1, wherein the optically sensitive layer comprises at least one material from the list of materials including semiconducting polymer, semiconducting organic small molecule, quantum dots, and metal-organic perovskite semiconductor.

10. The image sensor of claim 1, wherein the optically sensitive layer has an appropriate band alignment to the first charge-extracting layer to allow for good carrier collection when ‘on’ and poor hole extraction when ‘off.’

11. The image sensor of claim 1, wherein the optically sensitive layer can have a low number of deep trap states such that charge is quickly extracted.

12. The image sensor of claim 1, wherein the hole-extracting layer comprises at least one material from the list of materials including CoO, MoO3, WO3, NiO, ITO, AZO, and Spiro-OMeTAD.

13. The image sensor of claim 1, wherein the integrated circuit can control the bias across the optically sensitive layer to turn a device stack from “on” to “off.”

14. The image sensor of claim 1, wherein the off region can have a voltage width wide enough to include a full dynamic range of the image sensor.

15. An image sensor providing global electronic shutter, the image sensor comprising an integrated circuit;
a first electrode;
a first charge-extracting layer;
an optically sensitive layer;
and a second hole-extracting layer; wherein, in a first mode (the ‘on’ mode), electrons are extracted via the first charge-extracting layer into the first electrode, and wherein, in a second mode (the ‘off’ mode), an injection of electrons is prevented via an energetic barrier between a first contact and the first charge-extracting layer.

16. The image sensor of claim 15, wherein the first charge-extracting layer comprises at least one material from the list of materials including TiO2, ZnO, Ta2O5, CuO, Cu2O, ZrO2, Nb2O5, HfO2, and TiOxNy.

17. The image sensor of claim 15, wherein the first charge-extracting layer prevents the collection of holes by providing an energy barrier to hole collection by thermionic emission.

18. The image sensor of claim 15, wherein the first charge-extracting layer prevents the collection of holes by being substantially fully depleted of electrons such that recombination of photo-generated holes with electrons in the first charge-extracting layer is slow.

19. The image sensor of claim 15, wherein the first charge-extracting layer prevents the collection of holes by tunneling or trap-assisted tunneling through the first charge-extraction layer.

20. The image sensor of claim 15, wherein the first charge-extracting layer can be patterned into electrically isolated pixels.

21. The image sensor of claim 15, wherein the first charge-extracting layer can be a fast extractor of charge when ‘on.’

22. The image sensor of claim 15, wherein the optically sensitive layer comprises at least one material from the list of materials including semiconducting polymer, semiconducting organic small molecule, quantum dots, and metal-organic perovskite semiconductor.

23. The image sensor of claim 15, wherein the optically sensitive layer has an appropriate band alignment to the first charge-extracting layer to allow for good carrier collection when ‘on’ and poor hole extraction when ‘off.’

24. The image sensor of claim 15, wherein the optically sensitive layer can have a low number of deep trap states such that charge is quickly extracted.

25. The image sensor of claim 15, wherein the hole-extracting layer comprises at least one material from the list of materials including CoO, MoO3, WO3, NiO, ITO, AZO, and Spiro-OMeTAD.

26. The image sensor of claim 15, wherein the integrated circuit comprises silicon.

27. The image sensor of claim 15, wherein the integrated circuit can control the bias across the optically sensitive layer to turn a device stack from “on” to “off.”

28. The image sensor of claim 15, wherein the off region can have a voltage width wide enough to include a full dynamic range of the image sensor.
